(19) United States
(12) Patent Application Publication
(10) Pub. No.: US 2026/0304809 A1
(43) Pub. Date: Oct. 1, 2026

(54) III-V HETEROJUNCTION BIPOLAR TRANSISTOR AND ITS MANUFACTURING METHOD

(71) Applicant: COMMISSARIAT A L'ENERGIE ATOMIQUE ET AUX ENERGIES ALTERNATIVES, Paris (FR)

(72) Inventors: Hervé BOUTRY, Grenoble Cedex 09 (FR); Alexis DIVAY, Grenoble Cedex 09 (FR); Christophe DUBARRY, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/490,182

(22) PCT Filed: Apr. 29, 2024
(86) PCT No.: PCT/EP2024/061798

§ 371 Date: Dec. 4, 2025

(30) Foreign Application Priority Data
Jun. 6, 2023 (FR) FR2305684

(51) Int. Cl. H10D 10/80; H10D 10/01; H10D 62/13; H10D 62/17; H10D 62/824; H10D 80/30; H10D 84/01; H10D 84/60; H10D 84/85; H10W 80/00

(52) U.S. Cl. CPC H10D 10/821; H10D 10/021; H10D 62/136; H10D 62/177; H10D 62/824; H10D 80/30; H10D 84/0114; H10D 84/641; H10W 80/312; H10W 80/314; H10W 80/327; H10D 84/85

(57) ABSTRACT

A heterojunction bipolar transistor comprising, on a silicon substrate: a layer made of a first III-V material, a first mesa structure on said layer, comprising a collector layer, with the basis of a second III-V material N conductivity, and a base layer, with the basis of the second III-V material having a P+ conductivity, and a second mesa structure comprising an emitter layer with the basis of the first III-V material having an N conductivity. The transistor further includes collector, base, and emitter contacts made of a conductor material, suitable for a metallurgy of the metal levels of a CMOS transistor-b grated circuit. The transistor further includes an encapsulation layer made of a dielectric material, covering the first and second mesa structures, and the collector, base, and emitter contacts made of a dielectric material, suitable for an insulation of the metal levels of the CMOS transistor-based integrated circuit.

### TECHNICAL FIELD OF THE INVENTION

The present invention generally relates to microelectronic devices. It has a particularly advantageous application in producing heterojunction bipolar transistors HBT, for radiofrequency (RF) components.

### PRIOR ART

In the field of telecommunications and very high flow rate data transmission, typically for dataflows greater than 100 Gbits/s, it is necessary to have RF components operating at high working frequencies, typically at frequencies comprised at oscillation frequencies going up to 1 THz and beyond. For such RF components, an effective power amplification, having a cutoff frequency three to five times greater than the working frequency of the component, is required. Heterojunction bipolar transistors HBT, III-V heterojunction-based, are the more efficient for the power amplification at frequencies greater than 250 GHz.

Such HBT transistors are currently developed on small format substrate, typically less than 100 mm in diameter, and resort to architectures which are difficult to integrate industrially, based, for example, on submicronic air bridges or materials with a limited compatibility. Current HBT transistor technologies do not make it possible to consider a continuous “scaling”, i.e. a reduction of dimensions which is sufficient for the growth of performance targeted by the next generations of RF components. The compatibility of these technologies with so-called “Back End Of Line” (BEOL) interconnecting methods is further low. This limits the options of HBT transistor integration in integrated circuits based on a complementary metal-oxide-semiconductor CMOS transistor technology.

The document, “A. D. Carter et al., Si/InP Heterogeneous Integration Techniques from the Wafer-Scale (Hybrid Wafer Bonding) to the Discrete Transistor (Micro-Transfer Printing), 2018 IEEE SOI-3D-Subthreshold Microelectronics Technology Unified Conference (S3S), Burlingame, CA, USA, 2018, pp. 1-4” discloses an InP-based HBT transistor integration solution comprising an interconnecting part in BCB (Benzocyclobutan) connected by a hybrid bonding interface to a CMOS interconnecting part. This architecture remains difficult to implement. The assembly between the CMOS part and the HBT part must be done at the end of the method, after having producing all the interconnecting levels. Such an integration architecture limits the options of applications. HBT transistors cannot be integrated within the CMOS part, for example, between different CMOS interconnecting levels. The transmission losses between the different electronic functions of the integrated circuit, typically between the power amplification ensured by the HBT transistors and the antennas or the passive elements of the BEOL metal levels, are not optimised. The high frequency operation thus remains limited.

Another solution disclosed by the document, “T. E. Kazior et al., Progress and challenges in the direct monolithic integration of III-V devices and Si CMOS on silicon substrates, 2009 IEEE International Conference on Indium Phosphide & Related Materials, Newport Beach, CA, 2009, pp. 100-104” consists of co-integrating portions of III-V components by local epitaxy within the CMOS stack, by preserving a separation space around these portions of III-V components. This solution limits the densification of the components of such a co-integrated circuit. The selective growth and the management of stresses during growth further complexifies the method.

There is therefore a need to improve the integration of HBT III-V transistors in a CMOS integrated circuit.

An aim of the present invention is to meet this need, in particular, by proposing an HBT transistor architecture and a more versatile and more compact integration system.

Another aim of the present invention is to propose a method for manufacturing such an HBT transistor, and an integration method.

The other aims, features and advantages of the present invention will appear upon examining the description below and the accompanying drawings. It is understood that other advantages can be incorporated.

### SUMMARY

To achieve this aim, according to an embodiment, a heterojunction bipolar transistor is provided, comprising, in a stack along a direction z on a silicon-based substrate:
a first layer made of a first III-V material having a first type of conductivity with a first N+doping level,
a first mesa structure on the first layer, comprising:
   a so-called collector layer, with the basis of a second III-V material having the first type of conductivity with a second N doping level, and
   a so-called base layer, with the basis of a third III-V material having a second type of conductivity with a first P+ doping level,
a second mesa structure on the first mesa structure, comprising an emitter layer with the basis of a fourth III-V material, having the first type of conductivity with a third N doping level.

The transistor further comprises a collector contact on the first layer, at the border of the first mesa structure, a base contact on the base layer, at the border of the second mesa structure, an emitter contact on the emitter layer. Advantageously, the collector, base and emitter contacts are with the basis of a conductor material suitable for a metallurgy of the metal levels of a complementary metal-oxide-semiconductor (CMOS) transistor-based integrated circuit. According to an option, the conductor material is taken from among W, Ti, TIN, Ni and its NiSi, NiPt, and Cu alloys.

The transistor further comprises an encapsulation layer with the basis of a dielectric encapsulation material, said encapsulation layer covering the first layer, the first and second mesa structures, and the collector, base and emitter contacts. Advantageously, the encapsulation layer is with the basis of a dielectric material suitable for an insulation of the metal levels of a complementary metal-oxide-semiconductor (CMOS) transistor-based integrated circuit. According to an option, the dielectric material is taken from among SiO₂, SiNₓ.

Thus, the HBT transistor can be easily and directly integrated in a CMOS transistor-based integrated circuit. In the scope of development of the present invention, it has been observed by simulation of expected performance for the HBT transistor, that the choice of materials suitable for a BEOL-type integration made it possible to reach a cutoff frequency of around 1 THz, which is compatible with the working frequencies targeted in the range 220 GHz to 325 GHz. Contrary to the prejudices of the prior art, which recommends the use of BCB for the intermetallic dielectric and of noble metals for the contacts to obtain the required performance, it has been shown in the scope of the present invention that an HBT transistor architecture based on conductor and dielectric materials suitable for a BEOL-type integration was sufficient to obtain the required performance, with a performance level of around 80% to 85% of the reference performance level established for HBT transistors using BCB and noble metals.

The invention also relates to a method for producing a heterojunction bipolar transistor comprising at least the following steps:
a provision of a stack, comprising along a direction z, a silicon-based substrate, the first layer made of a first III-V material having a first type of conductivity with a first N+ doping level,
a formation, by epitaxy, on the first layer of a so-called collector layer, with the basis of a second III-V material having the first type of conductivity with a second N doping level, and
a formation, by epitaxy, on the collector layer of a so-called base layer, with the basis of a third III-V material having a second type of conductivity with a first P+doping level,
a formation, by epitaxy, on the base layer of a so-called emitter layer, with the basis of a fourth III-V material having the first type of conductivity with a third N doping level,
a first mesa-form structuration of the collector and base layers, configured to form a first mesa structure having a dimension L1 along a direction y perpendicular to the direction z,
a second mesa-form structuration of the emitter layer, configured to form a second mesa structure having a dimension L2 less than the dimension L1 along the direction y,
a formation of a collector contact on the first layer, preferably at the border of the first mesa structure,
a formation of a base contact on the base layer, at the border of the second mesa structure,
a formation of an emitter contact on the emitter layer, said collector, base and emitter contacts being formed with the basis of an electrically conductive material suitable for a metallurgy of the metal levels of a complementary metal-oxide-semiconductor (CMOS) transistor-based integrated circuit,
a formation of at least one encapsulation layer covering the first layer, the first and second mesa structures, the collector, base and emitter contacts, said encapsulation layer being formed with the basis of a dielectric material suitable for an insulation of the metal levels of a complementary metal-oxide-semiconductor (CMOS) transistor-based integrated circuit,
A planarisation of the at least one encapsulation layer.

Advantageously, at each brick of the method for manufacturing the III-V semiconductor-based HBT transistor, corresponding to the main steps of manufacturing the emitter, base and collector contacts, steps of planarising the wafer are carried out. These planarisation steps can be included in a dama-scene-type approach. The planarisation steps make it possible to adapt the method for manufacturing the HBT transistor to the current manufacturing modes of on-silicon integrated circuits, of the advanced CMOS and BiCMOS type. This approach is clearly different from native on-substrate III-V technologies, such as taught by document US2021391321A1. It makes it possible to obtain the following advantages:
a compatibility with transfer techniques by functional wafer chip “Direct Hybrid Bonding” (for example, a 5 mm BiCMOS wafer obtained at the “back end of line” BEOL). These techniques require an excellent planarity of the two parts to be bonded or to be connected, typically a surface topology less than 50 nm “peak to valley”. This level of surface quality to be bonded and to be interconnected can only be reached when each part is developed in BEOL CMOS technologies. This transfer by “Direct Hybrid Bonding” makes it possible to continue the “back end of line” method, which makes it possible to consider other improvements and functionalisations of the device (rear face post-method, collector contact directly on this face, for example).
a compatibility with the usual 200 mm and 300 mm tools and equipment used in the CMOS microelectronics industry. With the device being encapsulated in an oxide-based encapsulation layer typically, the resolution for the formation of the contacts can be highly improved (up to around 20 nm in 300 mm CMOS technology, for example). On the contrary, standard III-V technologies using air bridges can only contact the emitter for an emitter contact dimension WE≥200 nm. For an emitter contact dimension WE<200 nm, the reconnection must be made through a polymer coating (polyimides, BCB resin, etc.). This technique also limits the contact dimension reachable at around 130 nm. This technique however induces parasites. It further limits the manufacture of substrate formats less than 100 mm.
a compatibility with substrate sizes of 200 mm and 300 mm, instead of dimensions limited to 100 mm for the usual III-V substrates.

The invention also relates to an integration system and a method for integrating such an HBT transistor.

The system of integrating at least one heterojunction bipolar transistor according to the invention typically comprises, in a stack along a direction z:
a first silicon-based substrate,
a layer comprising complementary metal-oxide-semiconductor CMOS transistors and first metal interconnecting levels connected to said CMOS transistors,
a bonding layer comprising a hybrid bonding-type interface, comprising electrical connections with the first metal interconnecting levels connected to the CMOS transistors,
a layer comprising at least one heterojunction bipolar transistor, and second metal interconnecting levels inserted between the bonding layer and the layer comprising the at least one heterojunction bipolar transistor, said second metal interconnecting levels being electrically connected to the bonding layer and to the at least one heterojunction bipolar transistor.

The method for integrating at least one heterojunction bipolar transistor according to the invention typically comprises:
a provision of a first stack comprising, along a direction z:
   a first silicon-based substrate,
   a layer comprising complementary metal-oxide-semiconductor CMOS transistors, and first metal interconnecting levels connected to said CMOS transistors,
   a first part of a bonding layer comprising a hybrid bonding-type interface, comprising electrical connections with the first metal interconnecting levels connected to the CMOS transistors,
a provision of a second stack comprising, along a direction z:
   a second silicon-based substrate,
   a layer comprising at least one heterojunction bipolar transistor according to the invention, and second metal interconnecting levels connected to said heterojunction bipolar transistor,
   a second part of a bonding layer comprising a hybrid bonding-type interface, comprising electrical connections with said second metal interconnecting levels connected to the heterojunction bipolar transistor,
a hybrid bonding of the second part of the bonding layer on the first part of the bonding layer,
a removal of the second silicon-based substrate,
a formation, on the layer comprising the at least one heterojunction bipolar transistor, of at least one third interconnecting levels. According to an option, the at least one third interconnecting level comprises a so-called thick metal layer having a thickness, at least twice greater than the different metal thicknesses of the first and second metal interconnecting levels located under the layer comprising the at least one heterojunction bipolar transistor. The thick metal layer typically has a thickness greater than or equal to 1um, for example, around 3 μm.

Thus, the integration of the HBT transistors is done closest to the BEOL metal levels. The HBT transistor-based amplification circuits can thus be interconnected with the components and the passive elements of the CMOS circuits with reduced connection distances. Such an integration system has an improved compactness. This makes it possible to limit the transmission losses linked to too long HBT/CMOS interconnections. An RF system based on such an architecture can advantageously operate at a higher frequency. The energy efficiency, in particular, the electrical yield of the system, is also improved.

The HBT transistor and the integration system of this HBT transistor advantageously make it possible to produce compact and optimised RF circuit architectures, having improved RF performances.

### BRIEF DESCRIPTION OF THE FIGURES

The aims, objectives, as well as the features and advantages of the invention will best emerge from the detailed description of embodiments of the latter, which are illustrated by the following accompanying drawings, in which:

FIGS. 1 to 34 schematically illustrate steps of a method for producing an HBT transistor according to an embodiment of the present invention.

FIGS. 35 and 36 schematically illustrate steps of a method for producing an HBT transistor according to another embodiment of the present invention.

FIGS. 37 to 39 schematically illustrate a method for integrating and a system for integrating an HBT transistor in a CMOS integrated circuit according to another embodiment of the present invention.

FIG. 40 has an embodiment, in particular, with a particular example of forming contacts. The drawings are given as examples and are not limiting of the invention. They constitute principle schematic representations intended to facilitate the understanding of the invention, and are not necessarily to the scale of practical applications. In particular, in the principle diagrams, the thicknesses of the different layers and portions, and the dimensions of the patterns and structures are not representative of reality.

### DETAILED DESCRIPTION

Before starting a detailed review of embodiments of the invention, optional features are stated below, which can optionally be used in association or alternatively:

According to an example, the heterojunction bipolar transistor comprises, in a stack along a direction z on a silicon-based substrate:
a first layer made of a first III-V material having a first type of conductivity with a first N+ doping level,
a first mesa structure on the first layer, comprising:
   a so-called collector layer, with the basis of a second III-V material having the first type of conductivity with a second N doping level, and
   a so-called base layer, with the basis of a third III-V material having a second type of conductivity with a first P+doping level,
a second mesa structure on the first mesa structure, comprising an emitter layer with the basis of a fourth III-V material having the first type of conductivity with a third N doping level.
a collector contact on the first layer, at the border of the first mesa structure, a base contact on the base layer, at the border of the second mesa structure, an emitter contact on the emitter layer, the collector, base and emitter contacts being with the basis of a conductor material, typically with the basis of a conductor material taken from among W, Ti, TiN, Cu, Ni and its NiPt, NiSi alloys,
an encapsulation layer with the basis of a dielectric encapsulation material, said encapsulation layer covering the first layer, the first and second mesa structures, and the collector, base and emitter contacts, the encapsulation layer being with the basis of a dielectric material, typically with the basis of a dielectric material taken from among SiO₂, SiN, Al₂O₃, SiCO, HfO₂.

According to an example, the dielectric material is taken from among SiO₂, SiN, Al₂O₃, SiCO, HfO₂. These materials are advantageously fully compatible with BEOL methods in CMOS technology.

According to an example, the conductor material is taken from among W, Ti, TiN, Cu, Nb, Ni and its NiPt, NiSi alloys. These materials are advantageously fully compatible with BEOL methods in CMOS technology.

According to an example, the first and fourth III-V materials are InP-based, and the second and third III-V materials are InGaAs-based.

According to another example, the second III-V material is InP-based, and the third III-V material is GaAsSb-based, and the fourth III-V material is InGaP- and/or InP-based.

According to an example, the first layer made of a first III-V material is directly on the silicon-based substrate. According to another example, an interlayer, typically a bonding layer with the basis of a dielectric or metal material, is inserted between the first layer made of a first III-V material and the silicon-based substrate.

According to an example, the base contact has a central portion and a peripheral portion around the central portion such that the peripheral portion has a thickness less than that of the central portion. The thickness of the peripheral portion of the base contact decreases by moving away from the central portion. This typically makes it possible to decrease a parasitic capacity between the base contact and the emitter contact.

According to an example, the collector contact has a central portion and a peripheral portion around the central portion, such that the peripheral portion has a thickness less than that of the central portion. The thickness of the peripheral portion of the collector contact decreases by moving away from the central portion. This typically makes it possible to decrease a parasitic capacity between the collector contact and the base contact and/or the emitter contact.

According to an example, the method for producing a heterojunction bipolar transistor comprises at least the following steps:
a provision of a stack comprising, along a direction z, a silicon-based substrate, a dielectric layer, a first layer made of a first III-V material having a first type of conductivity with a first N+ doping level,
a formation, by epitaxy, on the first layer of a so-called collector layer, with the basis of a second III-V material having the first type of conductivity with a second N doping level, and
a formation, by epitaxy, on the collector layer of a so-called base layer, with the basis of a third III-V material, having a second type of conductivity with a first P+ doping level,
a formation, by epitaxy, on the base layer of a so-called emitter layer, with the basis of a fourth III-V material having the first type of conductivity with a third N doping level,
a first mesa-form structuration of the collector and base layers, configured to form a first mesa structure having a dimension L1 along a direction y perpendicular to the direction z,
a second mesa-form structuration of the emitter layer, configured to form a second mesa structure having a dimension L2 less than the dimension L1 along the direction y,
a formation of a collector contact on the first layer, preferably at the border of the first mesa structure,
a formation of a base contact on the base layer, at the border of the second mesa structure,
a formation of an emitter contact on the emitter layer, said collector, base and emitter contacts being formed with the basis of an electrically conductive material, typically with the basis of an electrically conductive material taken from among W, Ti, TiN, Cu,
a formation of at least one encapsulation layer covering the first layer, the first and second mesa structures, the collector, base and emitter contacts, said encapsulation layer being formed with the basis of a dielectric material, typically with the basis of a dielectric material taken from among SiO₂, SiN.

According to an example, the formations of the first and second mesa structures are done respectively by a first etching along z of the collector and base layers, and by a second etching along z of the emitter layer. Such a production method is generally called “top-down”. This makes it possible to better control the crystalline quality of the different layers and the dimensions of the different structures.

According to an example, the first and second etchings each comprise a wet isotropic etching step, such that the first and second mesa structures each have inclined flanks, respectively overhanging the first layer and the base layer. This makes it possible to reduce the parasitic capacities (in particular, under the collector). This makes it possible to produce self-aligned contacts.

According to another example, the first and second etchings each comprise a dry and wet mixed etching step.

According to an example, the following steps are carried out according to the following chronological order: formation of the emitter contact, then formation of the second mesa structure, then formation of the base contact, then formation of the first mesa structure, then formation of the collector contact. According to an example, the following steps are carried out according to the following chronological order: formation of the second mesa structure, then formation of the base contact, then formation of the emitter contact, then formation of the first mesa structure, then formation of the collector contact. The formation of the base contact before that of the emitter contact makes it possible to obtain a low base contact thickness more simply, with a limited number of steps, typically by chemical-mechanical polishing (CMP) without etching the base contact. The base contact can subsequently have an upper face substantially in one same plane as a lower face of the emitter contact. This also makes it possible to limit the presence of metal during the etching of the semiconductor layers which constitute the emitter. This avoids a metal contamination of the substrate or of the wafer.

According to an example, the formation of the collector contact comprises a first tungsten nitrogen plasma-enhanced deposition, intended to form a peripheral portion of the collector contact. The formation of the collector contact further comprises a tapering of the peripheral portion of the collector contact by preferable etching of the peripheral portion of the collector contact with regard to a central portion of the collector contact. This makes it possible to move the peripheral portion away from the collector contact with respect to the base contact. The parasitic capacity between the collector contact and the base contact is decreased. This also makes it possible to move the peripheral portion away from collector contact with respect to the emitter contact. The parasitic capacity between the collector contact and the emitter contact is decreased.

According to an example, the formation of the base contact comprises a first tungsten nitrogen plasma-enhanced deposition, intended to form a peripheral portion of the base contact. The formation of the base contact further comprises a tapering of the peripheral portion of the base contact by preferable etching of the peripheral portion of the base contact with respect to a central portion of the base contact. This makes it possible to move the peripheral portion away from the base contact with respect to the emitter contact. The parasitic capacity between the base contact and the emitter contact is decreased.

According to an example, the integration system further comprises, on the layer comprising the at least one heterojunction bipolar transistor, at least one third interconnecting level. The layer comprising the at least one HBT transistor is thus located between the first CMOS interconnecting levels and the at least one third interconnecting level. The third interconnecting level is typically a CMOS interconnecting level.

According to an example, the third interconnecting level comprises a so-called thick metal layer having a thickness at least twice greater than the different metal thicknesses of the first and second metal interconnecting levels located under the layer comprising the at least one heterojunction bipolar transistor. Such a thick metal layer comprises, for example, passive component patterns, such as transmission lines, antennas, etc.

According to an example, the thick metal layer is connected to the first layer made of a first III-V material of the heterojunction bipolar transistor by a thermal dissipation electrical connection, said thermal dissipation electrical connection acting as a collector contact for the heterojunction bipolar transistor. Such an electrical connection in the rear face of the HBT transistor, for the collector, makes it possible to best manage the heating and the thermal dissipation of the HBT transistor. The significant thickness of the thick metal layer typically makes it possible to form a radiator for the collector of the HBT transistor.

According to an example, the first layer made of a first III-V material of the layer comprising the at least one heterojunction bipolar transistor is continuous and covers, projecting along the direction z, totally the first silicon-based substrate. The first layer made of a first III-V material and the first silicon-based substrate are typically of the same dimensions in the plane normal to the direction z. This typically corresponds to the use of InPoSi (“InP on Silicon”) substrates, being able to advantageously reach large dimensions, for example, a diameter of 200 mm, even 300 mm. The option of designing HBT integration systems on CMOS of large dimensions improves the industrial implementation of this technology (less material losses and reduced cost).

According to an example, the first metal interconnecting levels connected to the CMOS transistors comprises between three and five metal layers.

Unless incompatible, it is understood that all of the optional features above can be combined so as to form an embodiment which is not necessarily illustrated or described. Such an embodiment is clearly not excluded from the invention. The features of an aspect of the invention, for example, the HBT transistor or the integration system, can be adapted mutatis mutandis to another aspect of the invention, for example, the production or integration methods.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer at least partially covers the second layer by being either directly in contact with it, or by being separated from it by at least one other layer or at least one other element.

A layer can moreover be composed of several sublayers of one same material or of different materials. The collector layer typically comprises different N-type layers, having different dopings and/or chemical compositions. The collector layer comprises, for example, several InP layers with decreasing doping levels (N+, N−, along the direction z) in contact with an InGaAs layer with an N− doping level.

The emitter layer typically comprises different N-type layers, having different dopings and/or chemical compositions. The emitter layer comprises, for example, several InP layers with increasing doping levels (N−, N+, along the direction z), and optionally a highly N+ doped InGaAs layer in contact with the emitter contact.

The base layer typically comprises a highly P++ doped P-type InGaAs layer, for example, inserted between the N− InGaAs layer of the collector layer and the N− InP layer of the emitter layer.

By a substrate, a stack, a layer “with the basis” of a material A, this means a substrate, a stack, a layer comprising this material A only, or this material A and optionally other materials, for example alloy elements and/or doping elements. Thus, an InP-based layer extends, for example, from an InP, N− doped InP, N+ doped InP layer, etc. An InGaAs-based layer can comprise an N− InGaAs sublayer and one or more InP sublayers.

The doping ranges associated with the different types of doping indicated in the present application are as follows:
P++ or N++ doping: greater than 5×10¹⁹ cm⁻³
P+ or N+ doping: 1×10¹⁸ cm⁻³ to 5×10¹⁹ cm⁻³
P or N doping: 1×10¹⁷ cm⁻³ to 1×10¹⁸ cm⁻³
intrinsic doping: 1×10¹⁵ cm⁻³ to 1×10¹⁷ cm⁻³

By a material “suitable for” a metallurgy or an insulation of the interconnecting levels of a CMOS integrated circuit, this means a material used or useable for the CMOS integration and, in particular, in BEOL methods. According to an example, “suitable for” means “adapted to” or “appropriate for”, or also “compatible with”, or “capable of” even, “intended to”. A dielectric material suitable for an insulation of the interconnecting levels of a CMOS integrated circuit can be, without being limiting: SiO₂-, SiN-, SiON-, SiOC-, SiOCH-, SiCN—Al₂O₃-, HfO₂-based. An electrically conductive material suitable for a metallurgy of the interconnecting levels of a CMOS integrated circuit can, without being limiting: W-, Ti-, TiN-, Cu-, Nb-, Al-, Mo-, Ni-, NiSi-, NiPt-, Ni₂P-, Co-based, etc.

The word “dielectric” qualifies a material, the electrical conductivity of which is sufficiently low in the given application to serve as an insulator, typically for the intermetal layers of the BEOL levels. In the present invention, a dielectric material preferably has a dielectric constant less than 7.

The present invention enables, in particular, the manufacture of at least one III-V HBT transistor or of a plurality of III-V HBT transistors on an Si substrate. This substrate can be bulk, or also of the semiconductor on insulator type. The Si substrate can, for example, form part of an InPoSi (InP on Silicon) stack).

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A particular application of the invention relates to RF systems, in particular, RF amplification circuits. The invention can also be implemented more broadly for different microelectronic devices or components, for example, in the scope of analogue circuits or of mixed signal circuits (digital/analogue). Several embodiments of the invention implementing successive steps of the manufacturing method are described below. Unless explicitly mentioned, the adjective “successive” does not necessarily imply, even if this is generally preferred, that the steps following one another immediately, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of the phases of the method.

A preferably orthonormal system, comprising the axes x, y, z is represented in the accompanying figures. When one single system is represented in one same set of figures, this system is applied to all the figures of this set.

In the present patent application, the thickness of a layer is taken along a direction normal to the main extension plane of the layer. Thus, a layer typically has a thickness along z. The relative terms “on”, “surmounts”, “under”, “underlying” refer to positions taken along the direction z.

The terms “vertical”, “vertically” refer to a direction along z. The terms “horizontal”, “horizontally”, “lateral” refer to a direction in the plane xy. Unless explicitly mentioned, the thickness, the height and the depth are measured along z.

An element located “in vertical alignment with” or “to the right of” another element means that these two elements are both located on one same line perpendicular to a plane into which a lower or upper face of a substrate mainly extends, i.e. on one same line oriented vertically in the figures.

The terms “substantially”, “around”, “about” mean plus or minus 10%, and preferably plus or minus 5%. Moreover, the term “between . . . and . . . ” and equivalents mean that the limits are inclusive, unless mentioned otherwise.

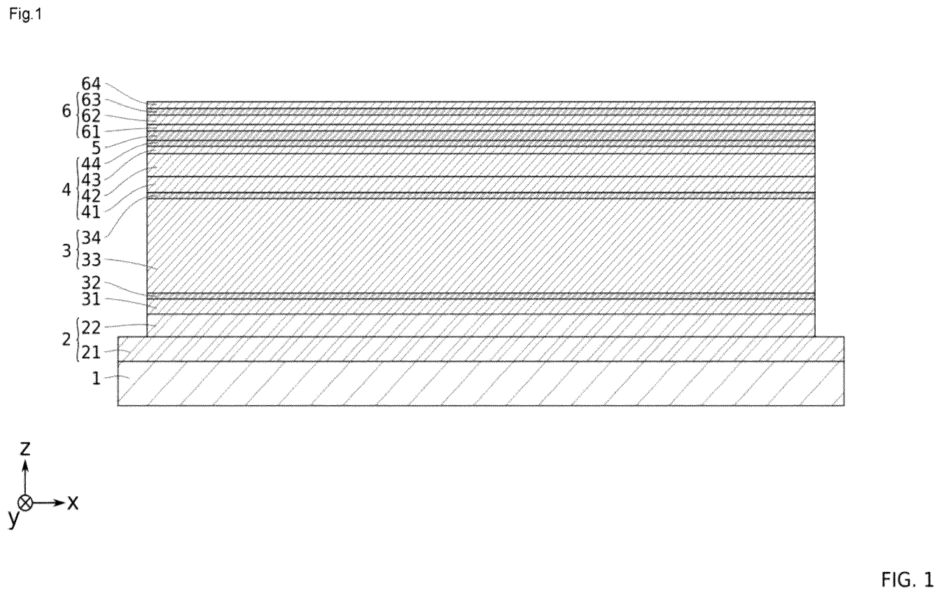

FIGS. 1 to 32 illustrate a first embodiment of the method for producing the HBT transistor. In this example of an embodiment, the HBT transistor is of the N-P-N type (emitter-base-collector), with an InGaAs/InP heterojunction. Other configurations can be fully considered. In particular, other III-V materials can be used for the junctions or heterojunctions, in a known manner. The following alloys can, in particular, be used for producing the HBT transistor: InGaAs, InP, InGaP, GaAsSb. A person skilled in the art will know how to adapt the example of the embodiment described below, according to these needs.

As illustrated in FIG. 1, a silicon-based substrate (Si substrate) is first provided. According to an option, a stack of layers 3, 4, 5, 6 with the basis of III-V materials, formed separately, can be transferred onto the silicon-based substrate 1, by SiO₂—SiO₂ bonding, for example. The silicon-based substrate 1 subsequently typically comprises a first SiO₂-based boding layer 21 and the stack subsequently typically comprises a second SiO₂-based bonding layer 22. In this case, the silicon-based substrate 1 and the stack with the basis of III-V materials can be assembled by molecular bonding between the first and second bonding layers 21, 22. The first bonding layer 21 can be thermal SiO₂-based. It typically has a thickness of around 200 nm. The second bonding layer 22 can be formed by chemical vapour deposition (CVD) on the stack of layers with the basis of III-V materials. It typically has a thickness of around 100 nm. In this case, of transferring the stack of layers with the basis of III-V materials onto the Si substrate, said stack has a lateral dimension, in the plane xy, for example, a diameter, typically less than the lateral dimension, for example, the diameter of the Si substrate, as illustrated in FIG. 1.

According to another option, the silicon-based substrate can typically be of the InPoSi type and comprise a silicon “bulk” part 1, a buried oxide (BOX) layer 2, surmounted by a superficial InP layer 31. Such an InPoSi substrate can be obtained by a method called “smart cut”, broadly known to a person skilled in the art. In this case, the stack of layers 3, 4, 5, 6 with the basis of III-V materials can be formed directly by epitaxy on the InPoSi substrate. Advantageously, the stack of layers with the basis of III-V materials has, in this case, a lateral dimension, in the plane xy, for example a diameter, substantially equal to the lateral dimension, for example, the diameter, of the InPoSi substrate.

Whatever the way in which the stack of layers with the basis of III-V materials is formed, either separately then transferred by SiO₂—SiO₂ bonding on the Si substrate, or directly by epitaxy on the InPoSi substrate, the stack preferably comprises, along z, and starting with the oxide layer 2:
an InP-based layer 31, which can be, as the case may be, an InP-based connecting layer with the second bonding layer 22 or a superficial InP layer of an InPoSi substrate. This layer 31 typically has a thickness of around 50 nm.
an InGaAs-based layer 32, which serves as an etching stop layer. In a known manner, an etching stop can be done by end-of-etching detection, by detecting the change in nature of the materials etched during the etching and/or by taking advantage of the etching selectivity of the materials of the layer to be etched and of the stop layer. This layer 32 typically has a thickness of around 20 nm.
an N+ doped InP-based layer 33, which ensures a good electrical conductivity under the collector of the HBT transistor. This layer 33 typically has a thickness of around 350 nm.
an N+ doped InGaAs-based layer 34, which ensures a good electrical conductivity under the collector of the HBT transistor. This layer 34 typically acts as an interface with the collector contact of the HBT transistor. This layer 34 typically has a thickness of around 20 nm. The layers 33, 34 can form a so-called subcollector layer 3.
an N+ doped InP-based layer 41, intended to form a part of the collector. This layer 41 typically has a thickness of around 50 nm.
an N− doped InP-based layer 42, intended to form a part of the collector. This layer 42 typically has a thickness of around 85 nm.
a second N− doped InP-based layer 43, intended to form a part of the collector. This layer 43 typically has a thickness of around 25 nm.
an N− doped InGaAs-based layer 44, intended to form a part of the collector. This layer 44 typically has a thickness less than or equal to 20 nm, for example, of around 10 nm or 5 nm. The layers 41, 42, 43, 44 typically form the collector layer 4. These different layers 41, 42, 43, 44 are preferably configured, such that the N-type doping progressively decreases between the layer 41 and the layer 44. This makes it possible to best accommodate the variations of conductivity and the mechanical stresses within the stack. These layers 41, 42, 43, 44 are typically sized by thickness and by doping, so as to manage the electrical field and the flow of the charges in the collector.
a P++ doped InGaAs-based layer 5, intended to form a first P/N junction with the layer 44. This layer 5 typically forms the base of the HBT transistor. It is typically directly connected to the base contact of the HBT transistor. This layer 5 typically has a thickness of around 28nm. Other materials can also be considered for this base layer 5, for example, GaAsSb.
an N− doped InP-based layer 61, intended to form a second P/N junction with the layer 5, of the heterojunction type. This layer 61 typically forms a part of the emitter. This layer 61 typically has a thickness of around 20 nm.
an N+ doped InP-based layer 62, intended to form a part of the emitter. This layer 62 typically has a thickness of around 30 nm.
an N+ doped InGaAs-based layer 63, intended to form a part of the emitter. This layer 63 typically acts as an interface with the emitter contact of the HBT transistor. This layer 63 typically has a thickness of around 20 nm. The layers 61, 62, 63 typically form the emitter layer 6.
an InP-based layer 64, which serves as an etching stop layer. This layer 64 typically has a thickness of around 20 nm.

After formation of the stack of layers with the basis of III-V materials, this stack is structured by different lithography and etching steps, and contacts are formed to produce the HBT transistor.

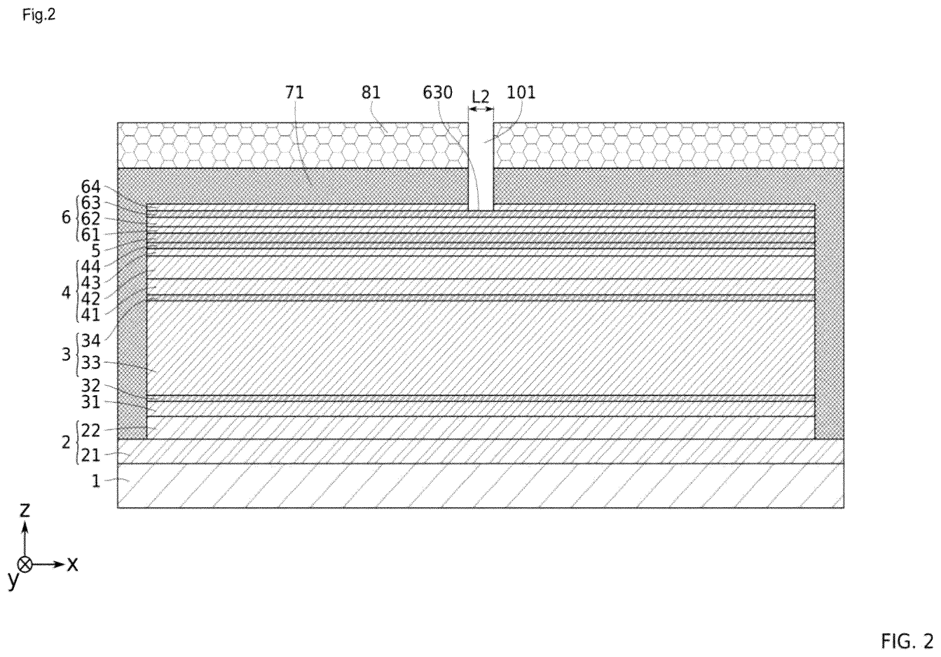

As illustrated in FIG. 2, a planarisation step can first be carried out. This step typically comprises a deposition of an SIN-based layer 71, intended, on the one hand, to fill the spaces bordering the stack of layers with the basis of III-V materials, and intended, on the other hand, to form a mask on the stack of layers with the basis of III-V materials. After deposition, a chemical-mechanical polishing (CMP) typically makes it possible to planarise the layer 71. The layer 71 surmounting the stack typically has a thickness of around 150 nm after planarisation.

A resin-based masking layer 81 is thus formed on the layer 71, then structured by lithography to form one or more openings 101 having a dimension L2 along x. The layer 71 is then etched through the opening 101, typically by plasma-based dry etching, or by reactive ion etching (RIE). The layer 64 of the stack is then etched through the opening 101, typically by selective wet etching with respect to the underlying layer 63. An upper face 630 of the layer 63 is thus exposed after the successive etchings through the opening 101.

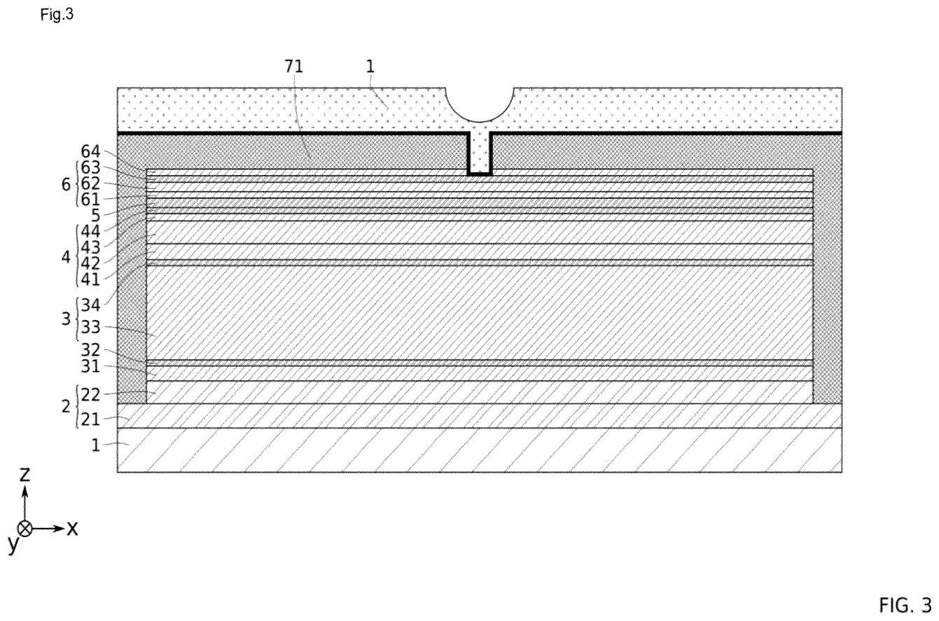

As illustrated in FIG. 3, the masking layer 81 is then removed, in a known manner, by a so-called “stripping” step, typically by O₂-based plasma. A deposition of a metal layer 11 is then performed, so as to fill the opening 101 of the layer 71. This metal layer 11 can comprise several sublayers, for example, Ti- and TiN-based sticking layers, of 10 nm thicknesses respectively, and a tungsten W-based main layer, of sufficient thickness to fill the opening of the layer 71. This tungsten W-based main layer has, for example, a thickness of around 225 nm.

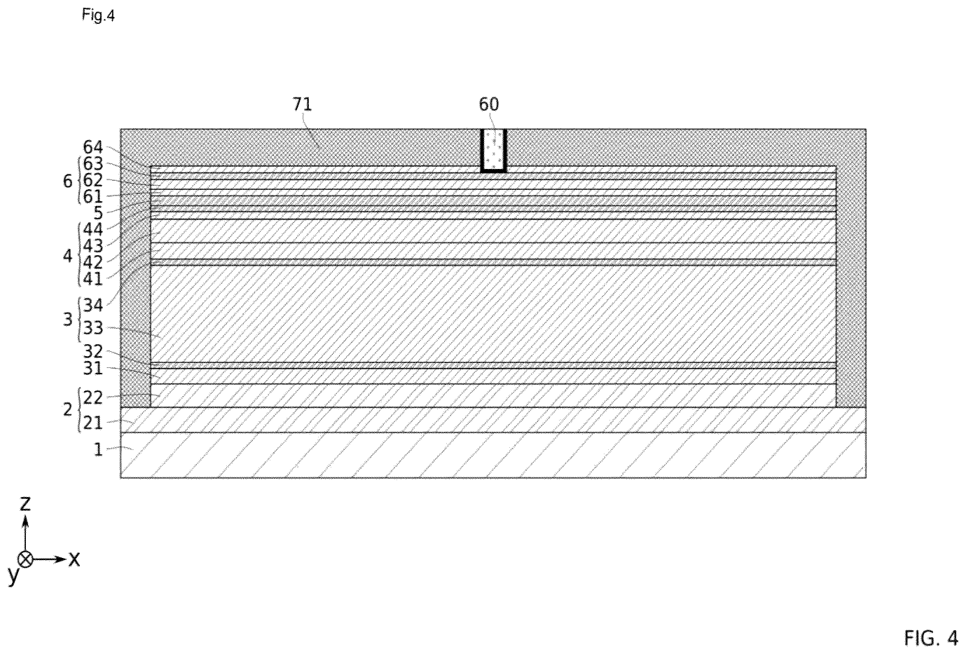

As illustrated in FIG. 4, a chemical-mechanical polishing is performed, so as to remove the excess metal deposited on the layer 71. The CMP is stopped on the layer 71, in order to preserve the metal layer portion in the opening of the layer 71. The emitter contact 60 is thus formed. It is, in this case, in contact with the N+ doped InGaAs-based layer 63.

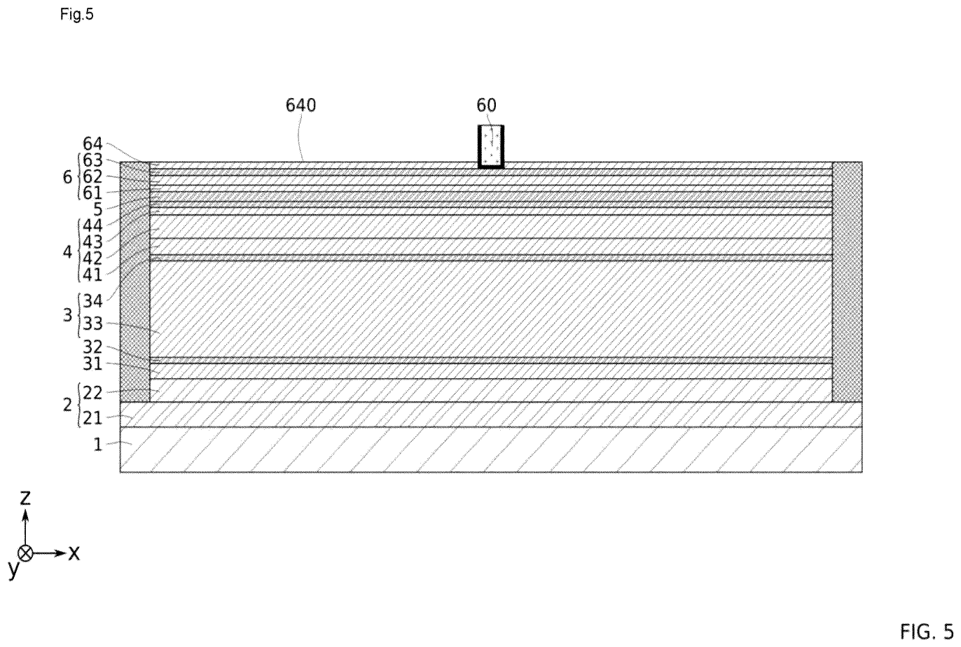

As illustrated in FIG. 5, a part of the layer 71 is then removed by etching, so as to expose an upper face 640 of the layer 64.

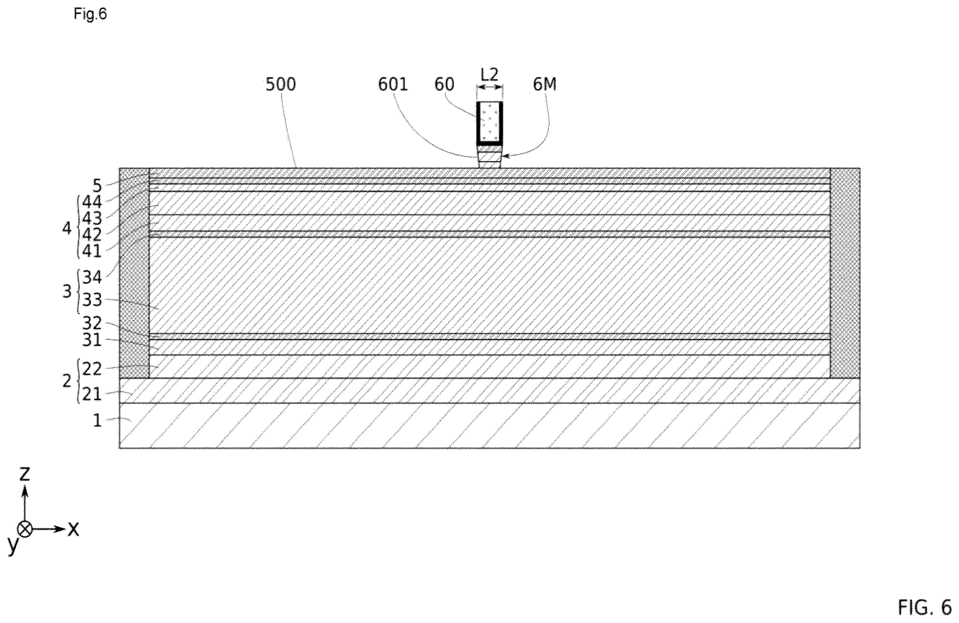

As illustrated in FIG. 6, the layers 64, 63, 62, 61 of the stack are then etched around the emitter contact 60, so as to expose an upper face 500 of the layer 5. The layers 64, 63, 62 and partially the InP-based layer 61 are typically etched by dry etching, stopping in the layer 61. A finishing etching by wet etching then makes it possible to remove the remaining part of the InP-based layer 61, selectively at the P++ InGaAs-based layer 5. A mesa structure 6M of dimension L2 along x is thus obtained under the emitter contact 60. This mesa structure 6M has flanks 601 which can be slightly inclined with respect to the vertical. This is typically due to the isotropic character of the etchings, in particular, of the wet etching. This also comes from the InP and InGaAs crystallography, insofar as certain crystalline planes are etched quicker than others.

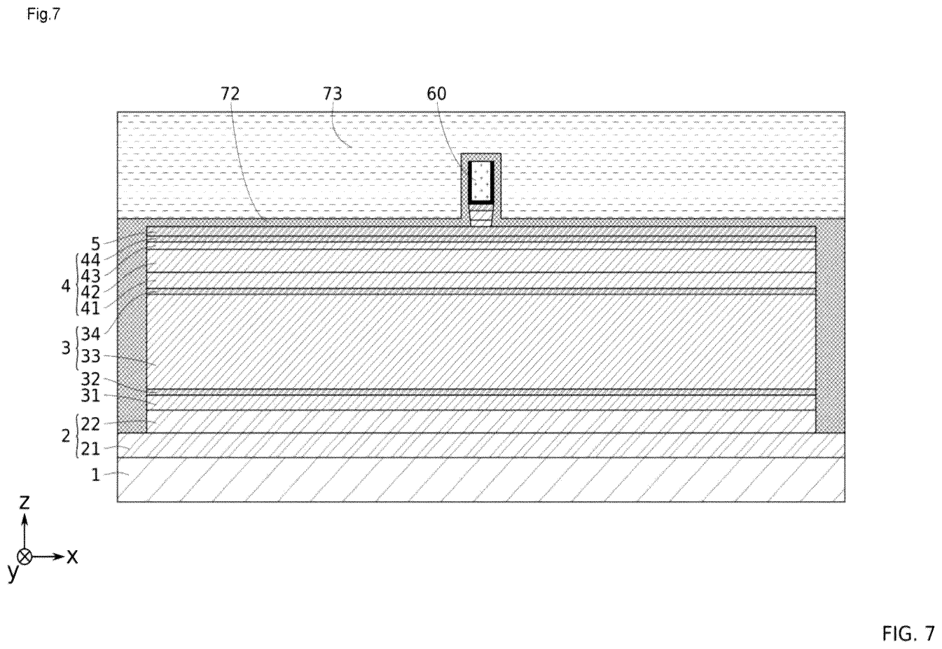

As illustrated in FIG. 7, an SIN-based layer 72 is then formed by conform deposition at 300° C. on the exposed face 500, and on the flanks 601 and the emitter contact 60. This layer 72 typically has a thickness of around 30 nm. An SiO₂-based layer 73 is then formed on the layer 72, for example, by deposition at 400° C. This layer 73 typically has a thickness of around 400 nm. A step of planarising by CMP is then carried out on the layer 73.

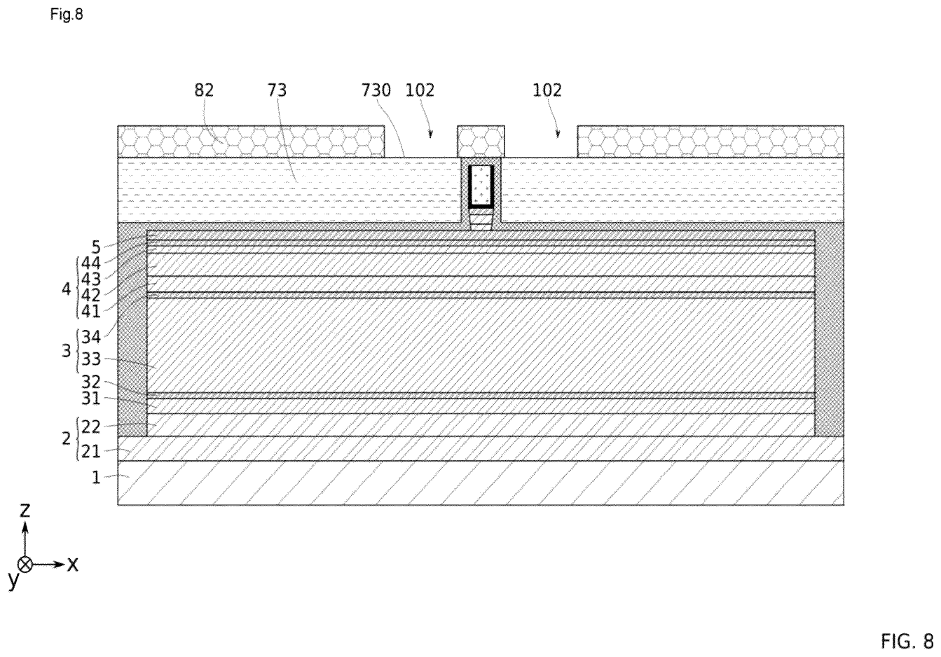

As illustrated in FIG. 8, the CMP of the layer 73 is typically stopped on the SiN-based layer 72 at the apex of the emitter contact 60. A resin-based masking layer 82 is thus formed on the layer 73 and on the layer portion 72 at the apex of the emitter contact 60, then structured by lithography to form openings 102, for example, by e-beam electron lithography. The openings 102 are formed on either side of the emitter contact 60. An upper face 730 of the layer 73 is thus exposed through the openings 102.

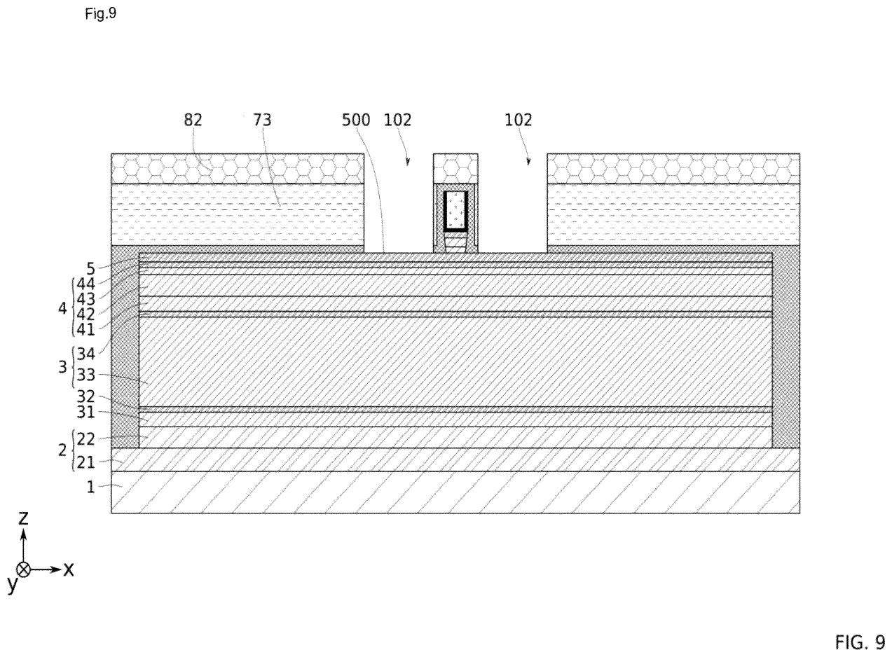

As illustrated in FIG. 9, the layers 73 and 72 are then etched through the openings 102, typically by dry etching. Stopping etching is done on the P++ InGaAs-based layer 5. An upper face 500 of the layer 5 is thus exposed after etching through the openings 102.

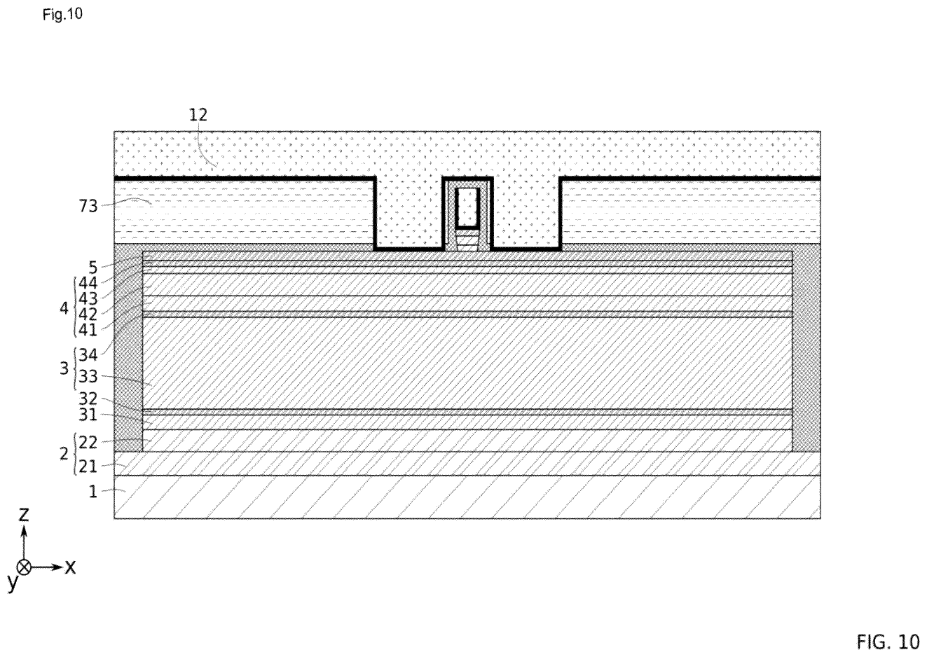

As illustrated in FIG. 10, the masking layer 82 is removed by “stripping”. A deposition of a metal layer 12 is then performed, so as to fill the openings 102 of the layer 73. This metal layer 12 can comprise several sublayers, for example, Ti- and TiN-based sticking layers, of 10 nm thicknesses respectively, and a tungsten W-based main layer, of sufficient thickness to fill the openings of the layer 73. This tungsten W-based main layer has, for example, a thickness of around 375 nm.

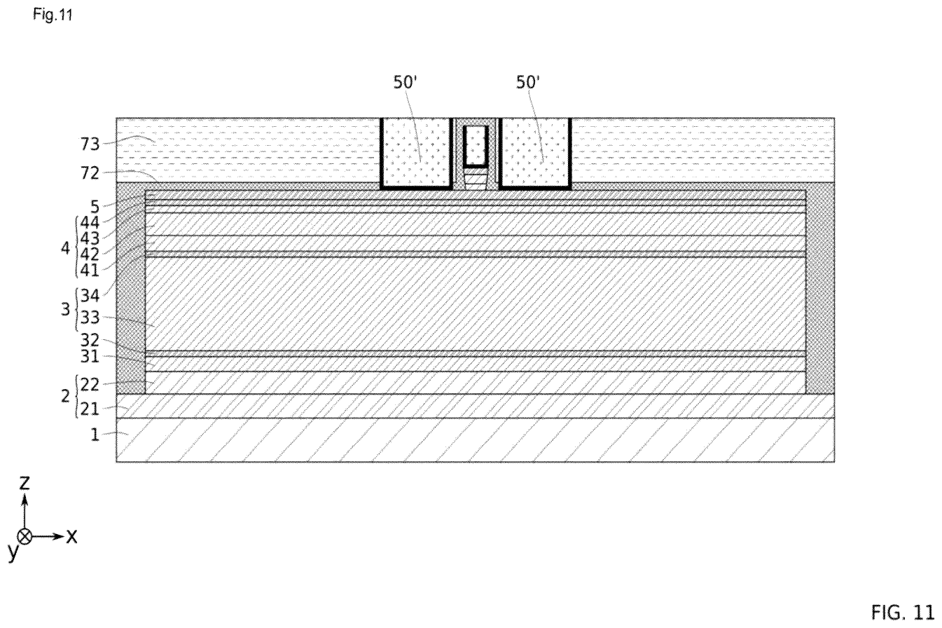

As illustrated in FIG. 11, a chemical-mechanical polishing is first performed, so as to remove the excess metal deposited on the layer 73. The CMP is stopped on the layer 73, in order to preserve the metal layer 12 portions 50′ in the openings of the layer 73.

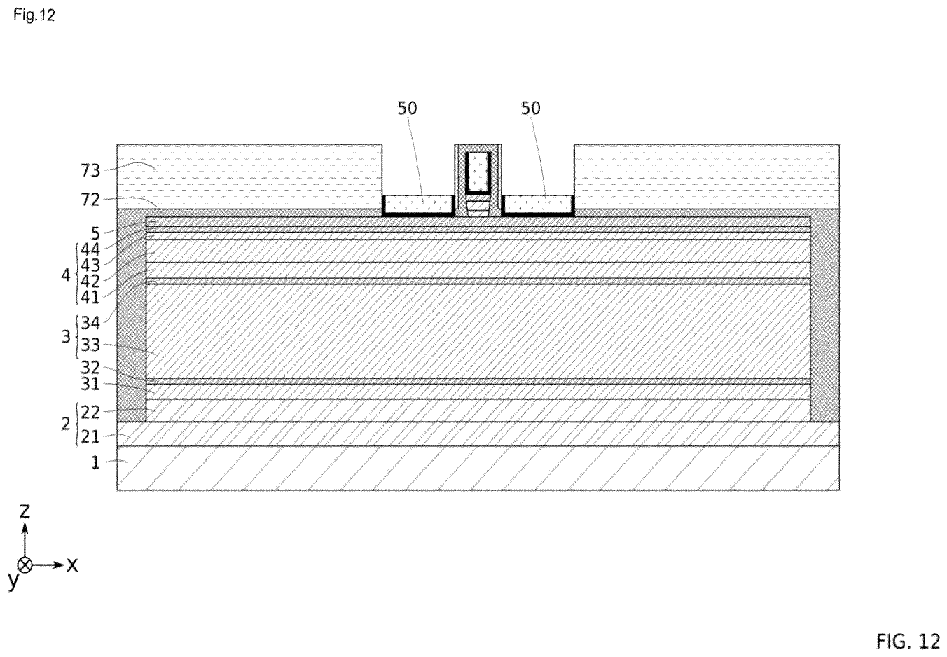

As illustrated in FIG. 12, these metal layer portions are then tapered to form the base contacts 50, typically such that the upper faces of the base contacts 50 are located under a plane passing through the lower face of the emitter contact 60. This makes it possible to minimise the parasitic capacities between the emitter contact 60 and the base contacts 50. Such a tapering typically makes it possible to reduce, by 55%, these parasitic capacities, compared with non-tapered base contacts 50′ and having a height substantially equal to the thickness of the layer 73, such as illustrated in FIG. 11.

The W metal layers can be tapered by potassium triiodide KII2-based wet etching. The Ti/TiN metal layer portions, at the flanks of the base contacts 50, can be removed by dry etching. Base contacts 50 directly in contact with the P++ doped InGaAs-based layer 5 are thus formed.

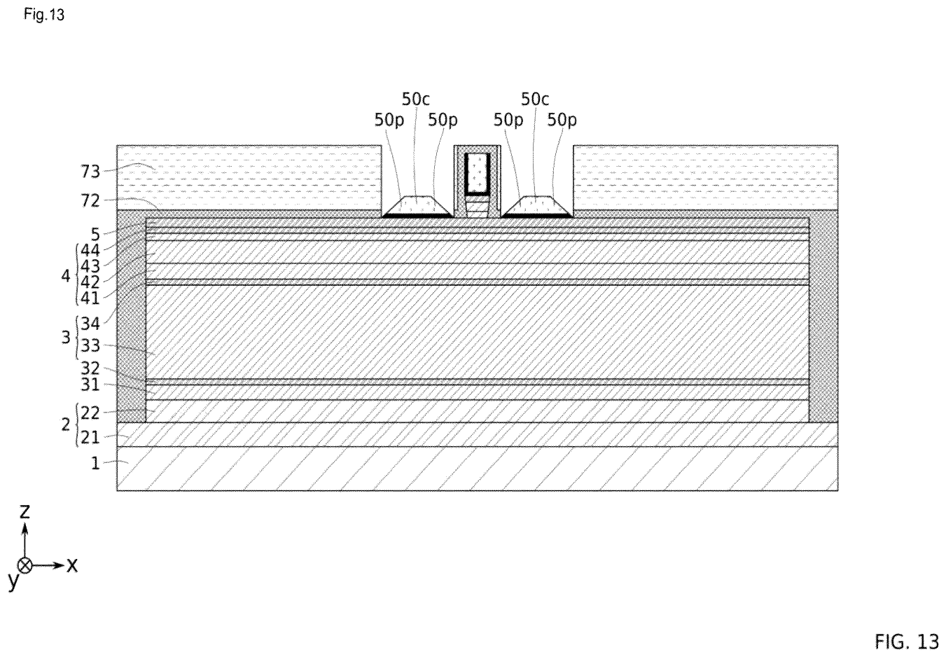

According to an option illustrated in FIG. 13, the tapering is performed differentially, in order to obtain peripheral portions 50p of the contact 50 which are thinner than the central portion 50c of the contact 50. Such a differential tapering can occur when the deposition of the tungsten W-based main layer is performed by N+nitrogen species plasma-enhanced CVD. The peripheral portions 50p of the contact 50 are thus preferably etched at the central portion 50c of the contact 50. The peripheral portions 50p typically have a profile of decreasing thickness from the central portion 50c. In this case, the parasitic capacities between the emitter contact 60 and the base contacts 50 are even more decreased. Such a differential tapering typically makes it possible to reduce, by 70%, these parasitic capacities, compared with non-tapered base contacts 50′ and having a height substantially equal to the thickness of the layer 73, such as illustrated in FIG. 11.

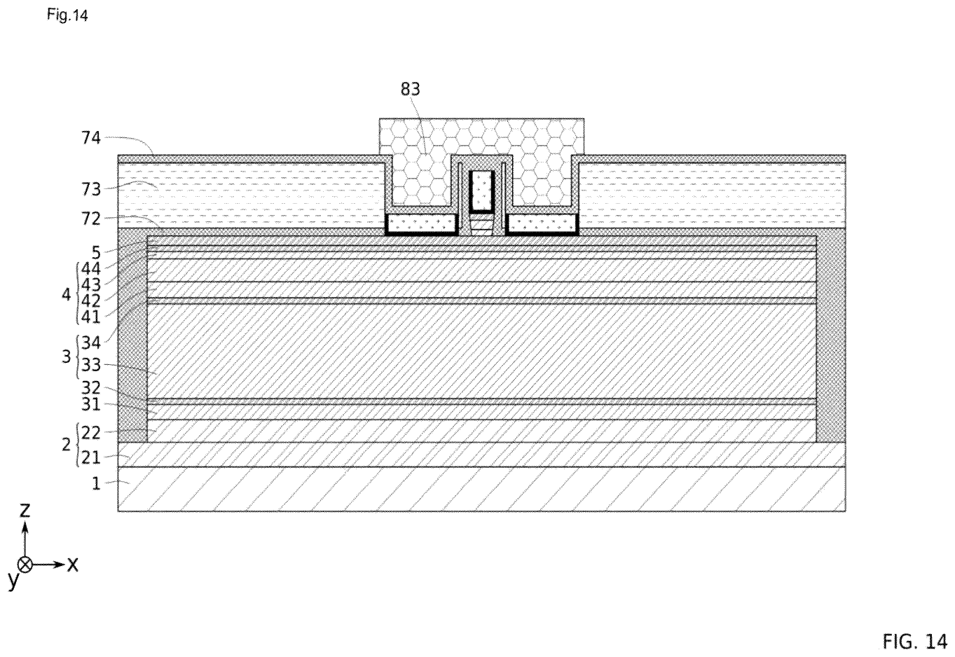

As illustrated in FIG. 14, an SIN-based layer 74 is then formed by conform deposition at 400° C. on the layer 73, and on the base contacts 50 and the emitter contact 60. This layer 74 typically has a thickness of around 60 nm. A resin-based masking layer 83 is thus formed and structured, for example, by e-beam electron lithography, above the base contacts 50 and the emitter contact 60, by preserving exposed layer parts 74 at the perimeter of the base contacts 50.

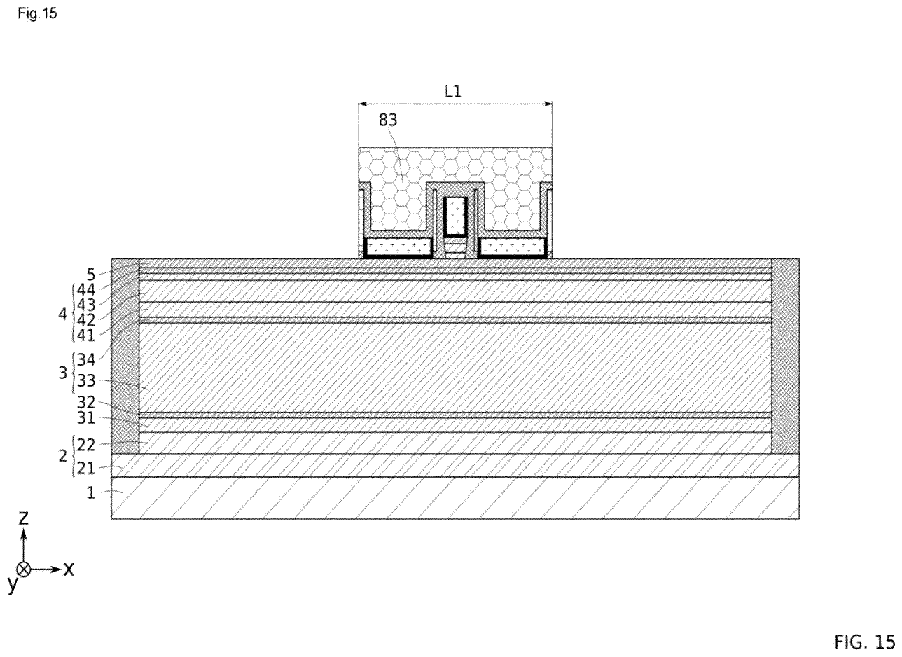

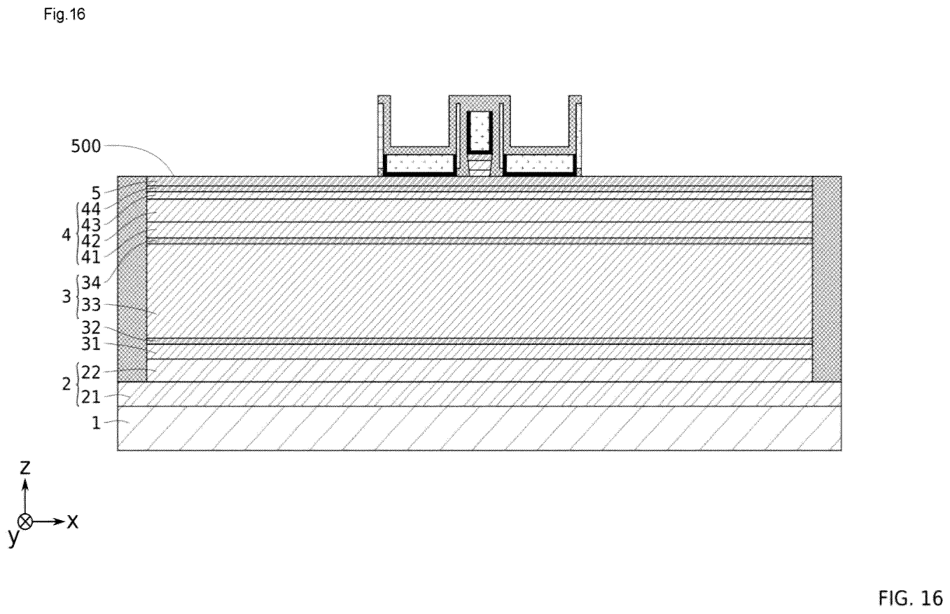

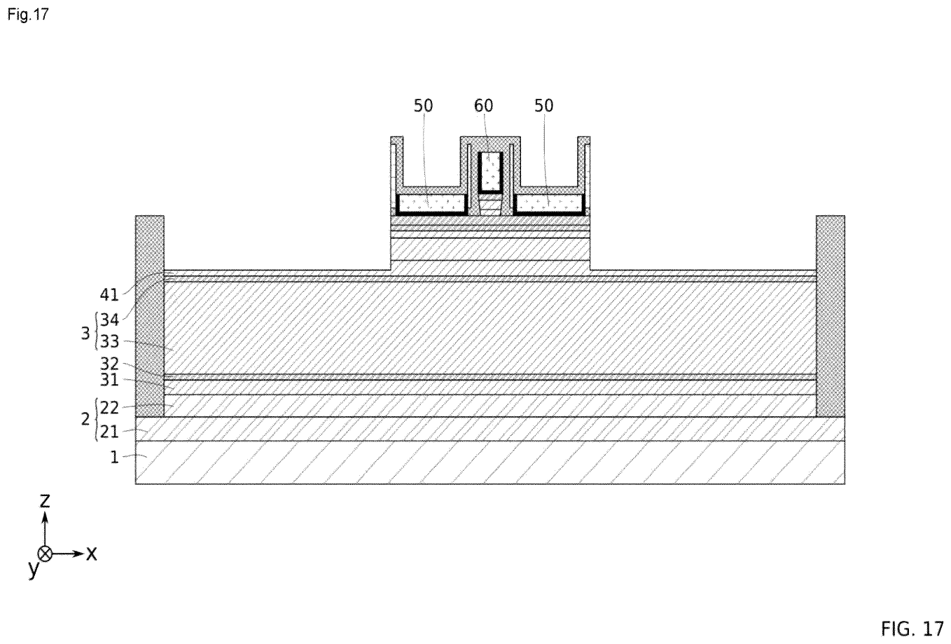

As illustrated in FIG. 15, the layers 74, 73 and 72 are then etched around the masking layer 83, typically by dry etching. Stopping etching is done on the P++InGaAs-based layer 5. An upper face 500 of the layer 5 is thus exposed after etching. The structure projecting from the layer 5, comprising the base contacts 50, the mesa structure 6M, the emitter contact 60 and the masking layer 83, typically has a dimension L1 along x. The masking layer 83 is then removed by “stripping” (FIG. 16). As illustrated in FIG. 17, the layers 5, 44, 43, 42 and 41 of the stack are then etched around the base contacts 50. The layers 5, 44, 43, 42 and partially the InP-based layer 41 are typically etched by dry etching, stopping in the layer 41. The partial dry etching of the InP-based layers 43, 42 and 41 can be configured to stop at an etching depth of around 140 nm from the interface between the layer 43 and the layer 44, so as to preserve a residual thickness of the layer 41 at the end of dry etching.

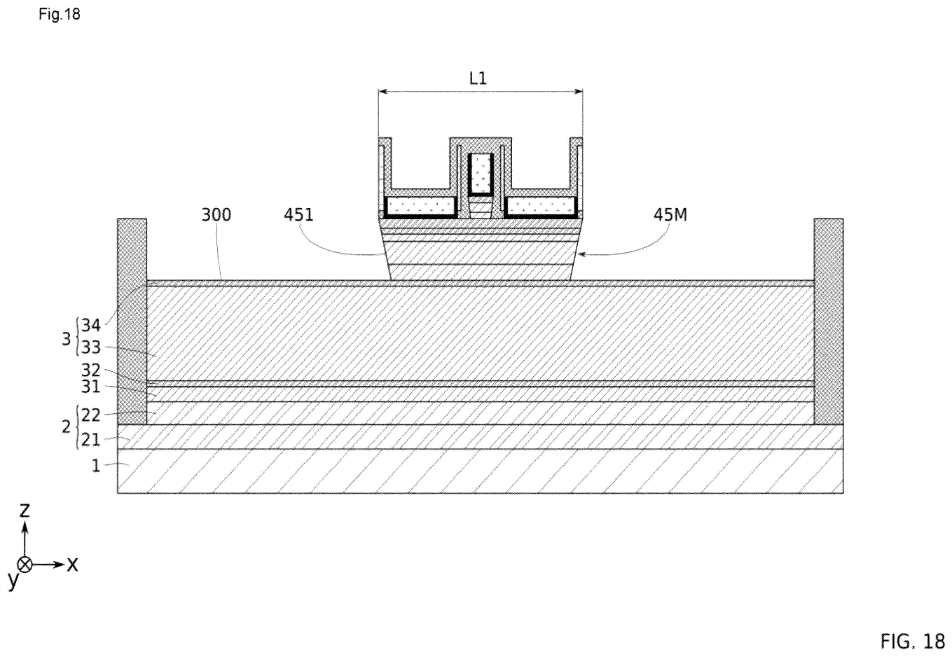

As illustrated in FIG. 18, a finishing etching by wet etching then makes it possible to remove the remaining part of the InP-based layer 41, preferably selectively at the N+ InGaAs-based layer 34, so as to expose an upper face 300 of the layer 34. A mesa structure 45M is thus obtained under the base contacts 50. This mesa structure 45M of dimension L1 along x typically has flanks 451 which can be slightly inclined with respect to the vertical. This is typically due to the isotropic character of the etchings, in particular of the wet etching.

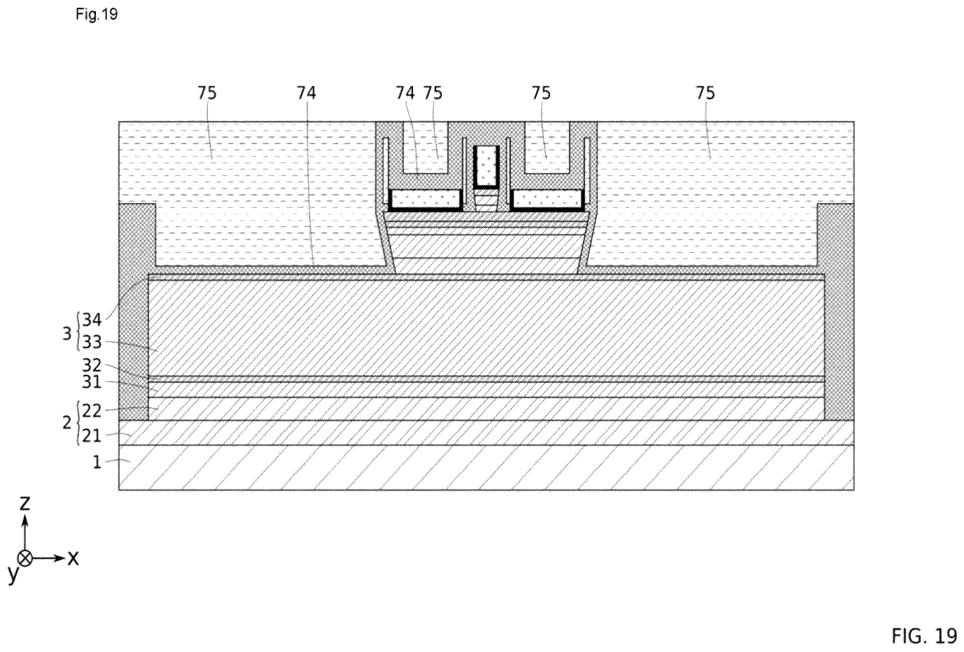

As illustrated in FIG. 19, an SiN-based layer 74 is then formed by conform deposition at 300° C. on the exposed face 300, and on the flanks 451, the base contacts 50 and the emitter contact 60. This layer 74 typically has a thickness of around 60 nm. An SiO₂-based layer 75 is then formed on the layer 74, for example, by deposition at 400° C. This layer 75 typically has a thickness of around 750 nm. A step of planarising by CMP is then carried out on the layer 75, stopping on the parts projecting from the SIN-based layer 74.

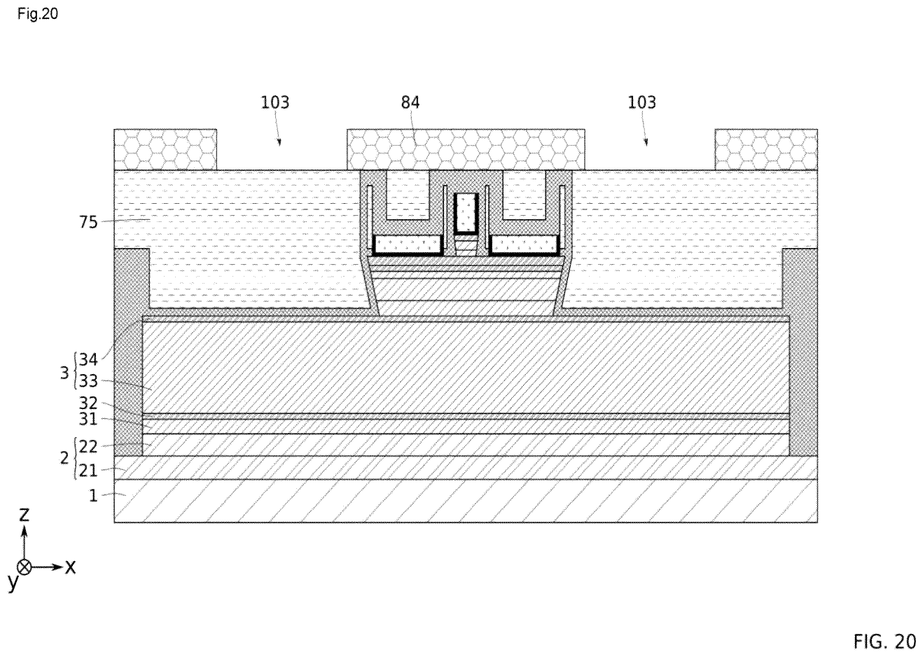

As illustrated in FIG. 20, a resin-based masking layer 84 is thus formed on the layer 75 and on the parts projecting from the layer 74, then structured by lithography to form openings 103. The openings 103 are formed on either side of the base contacts 50.

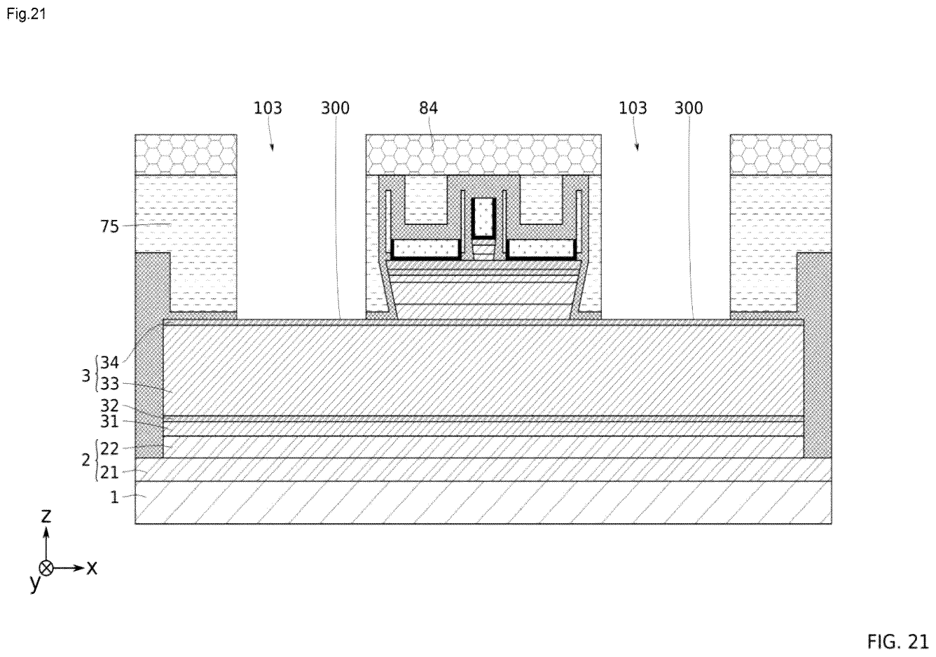

As illustrated in FIG. 21, the layers 75 and 74 are then etched through the openings 103, typically by dry etching. Stopping etching is done on the N+ InGaAs-based layer 34. An upper face 300 of the layer 34 is thus exposed after etching through the openings 103.

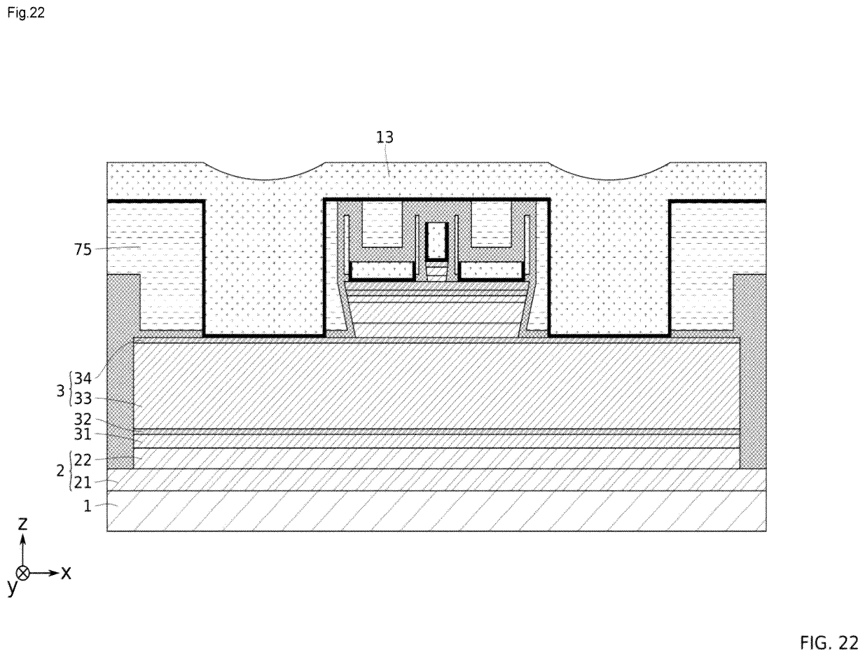

As illustrated in FIG. 22, the masking layer 84 is removed by “stripping”. A deposition of a metal layer 13 is then performed, so as to fill the openings 103 of the layer 75. This metal layer 13 can comprise several sublayers, for example Ti- and TiN-based sticking layers, of 10 nm thicknesses respectively, and a tungsten W-based main layer, of sufficient thickness to fill the openings of the layer 75. This tungsten W-based main layer has, for example, a thickness of around 750 nm.

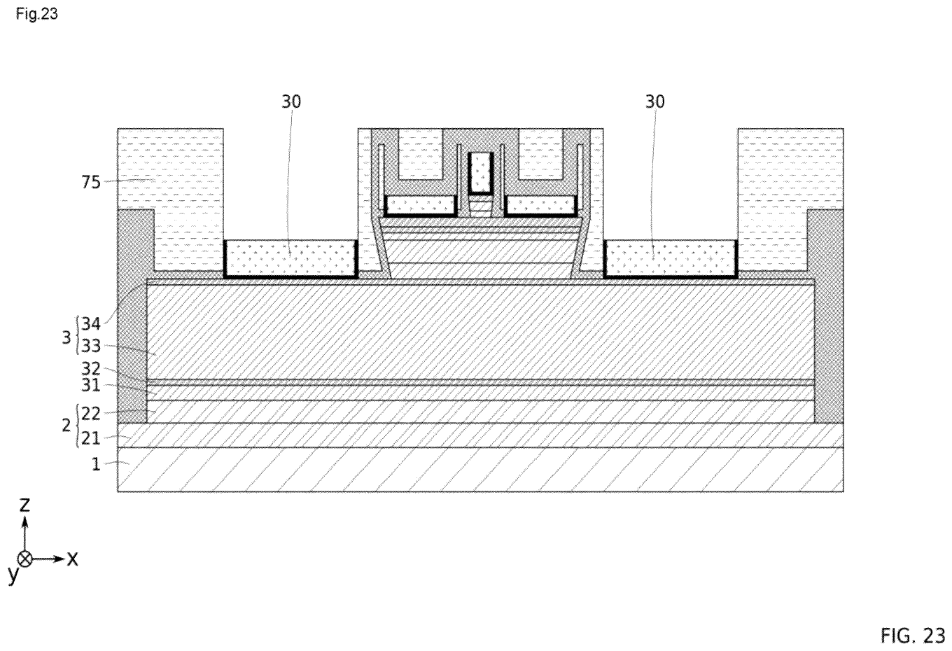

As illustrated in FIG. 23, a chemical-mechanical polishing is first performed, so as to remove the excess metal deposited on the layer 75. The metal layer portions 13 in the openings of the layer 75 are then tapered to form the collector contacts 30, typically such that the upper faces of the collector contacts 30 are located under a plane passing through the lower faces of the base contacts 50. This makes it possible to minimise the parasitic capacities between the collector contacts 30 and the base contacts 50. This also makes it possible to minimise the parasitic capacities between the collector contacts 30 and the emitter contact 60.

The W metal layer portions 13 can be tapered by potassium triiodide KII2-based wet etching, for example, over an etching depth of around 270nm. The Ti/TIN metal layer portions, at the flanks of the collector contacts 30, can be removed by dry etching. Collector contacts 30 directly in contact with the N+ doped InGaAs-based layer 34 are thus formed. According to an option, the collector contacts 30 can be tapered by differential tapering as above. The collector contacts 30 subsequently have a peripheral portion, relatively thinner than their central portion.

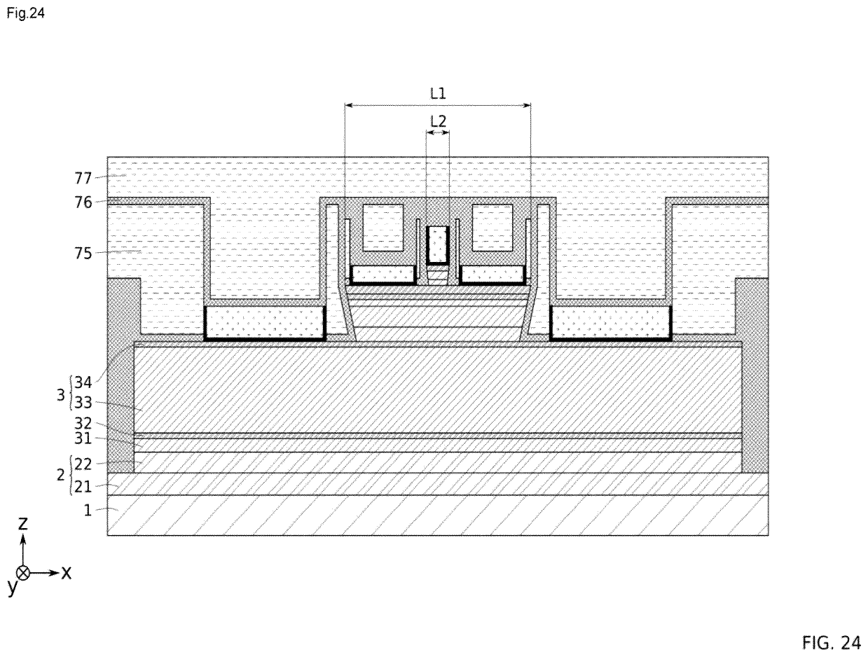

As illustrated in FIG. 24, an SIN-based layer 76 is then formed by conform deposition at 400° C. on the layer 75, and on the collector contacts 30. This layer 76 typically has a thickness of around 30 nm. An SiO₂-based layer 77 is then formed on the layer 76, for example, by deposition at 400° C. This layer 77 typically has a thickness of around 400 nm. A step of planarising by CMP is then carried out on the layer 77.

An HBT transistor with the basis of III-V materials, on Si substrate, and encapsulated by SiO2/SIN dielectric materials, is thus obtained. The following steps aim to form contact vias on the different emitter, base and collector contacts of the HBT transistor.

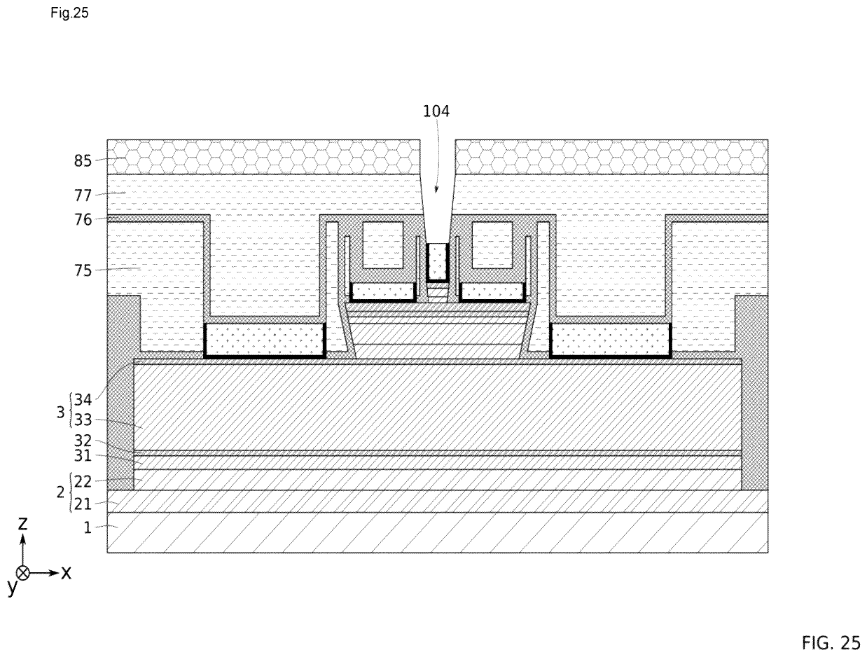

As illustrated in FIG. 25, a resin-based masking layer 85 is formed on the layer 77 and structured, typically by e-beam electron lithography. An opening 104 is made above the emitter contact 60, first in the layer 85, then in the stack of dielectric layers up to the emitter contact 60.

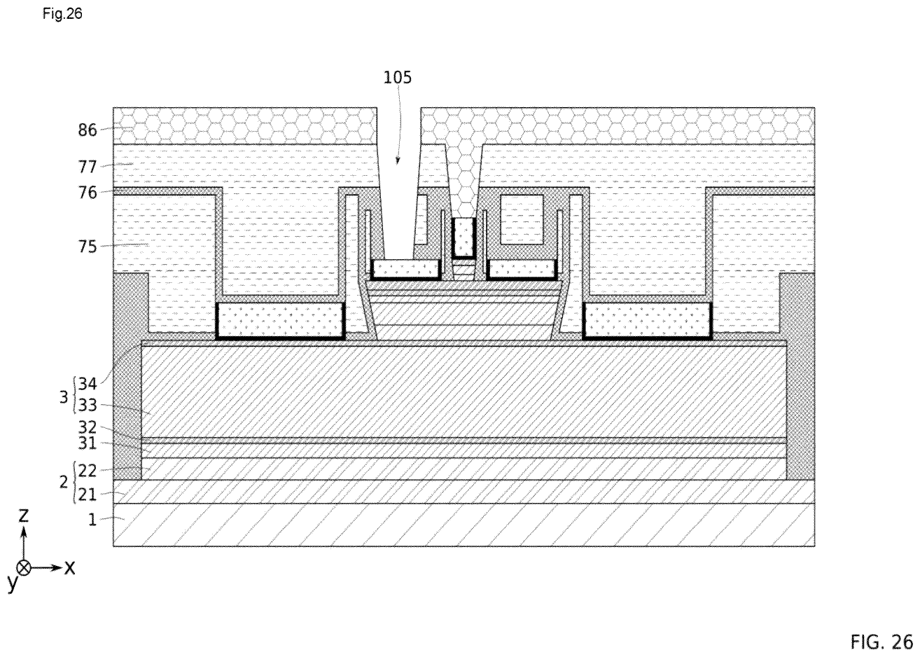

As illustrated in FIG. 26, after stripping of the masking layer 85, a new resin-based masking layer 86 is formed on the layer 77 and structured, typically by e-beam electron lithography. An opening 105 is made above the base contact 50, first in the layer 86, then in the stack of dielectric layers up to the base contact 50. The opening 104 above the emitter contact 60 is typically filled by the layer 86 at this stage.

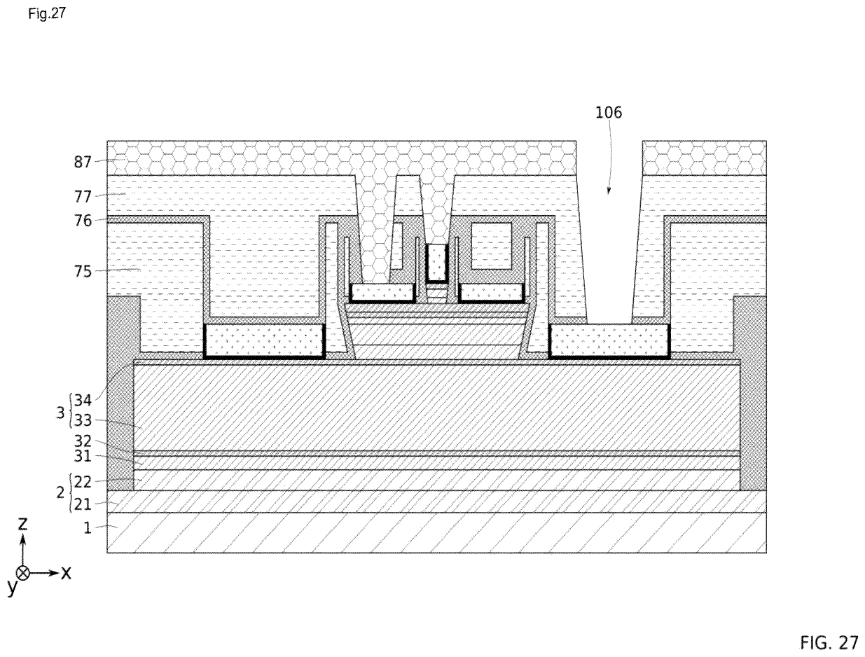

As illustrated in FIG. 27, after stripping of the masking layer 86, a new resin-based masking layer 87 is formed on the layer 77 and structured, typically by e-beam electron lithography. An opening 106 is made above the collector contact 30, first in the layer 87, then in the stack of dielectric layers, up to the collector contact 30. The openings 104, 105 respectively above the emitter contact 60 and the base contact 50 are typically filled by the layer 87 at this stage.

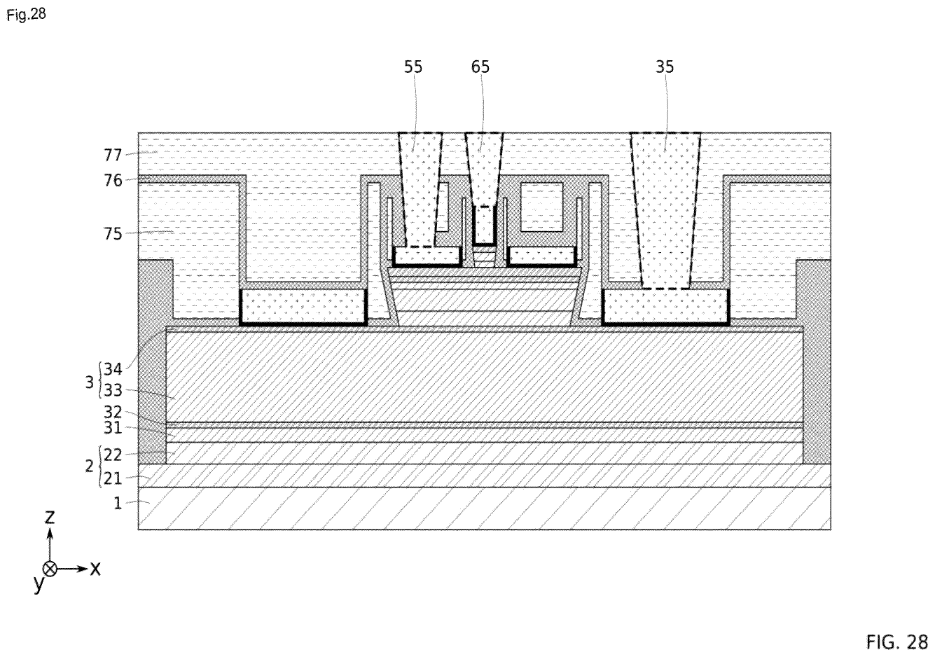

As illustrated in FIG. 28, after stripping of the masking layer 87, interconnections 55, 65, 35, also called contact vias, are formed in the openings 105, 104, 106, so as to respectively connect the base, emitter, collector contacts. A deposition of a metal layer is first performed, so as to fill the openings 105, 104, 106. This metal layer can comprise, as above, several sublayers, for example, Ti-and TiN-based sticking layers, of 10 nm thicknesses respectively, and a tungsten W-based main layer, of sufficient thickness to fill the openings 105, 104, 106. This tungsten W-based main layer has, for example, a thickness of around 700 nm. A chemical-mechanical polishing is then performed, so as to remove the excess metal deposited on the layer 77. The interconnections 55, 65, 35 are thus individualised.

The following steps aim to insulate the HBT transistor with respect to other components (not illustrated).

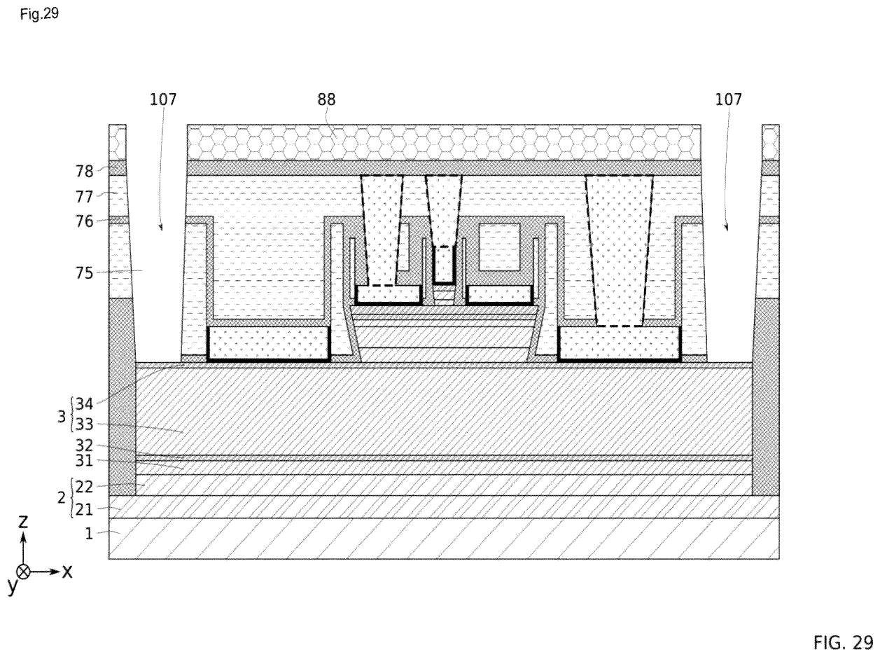

As illustrated in FIG. 29, an SiN-based layer 78 can be formed by deposition at 400° C. on the layer 77, and on the interconnections 55, 65, 35. This layer 78 typically has a thickness of around 150 nm. A resin-based masking layer 88 is formed on the layer 78, and then structured by lithography. Openings in the form of trenches 107 are made around the HBT transistor, typically around the collector contacts 30, first in the layer 88, then in the stack of dielectric layers up to the N+ InGaAs-based layer 34.

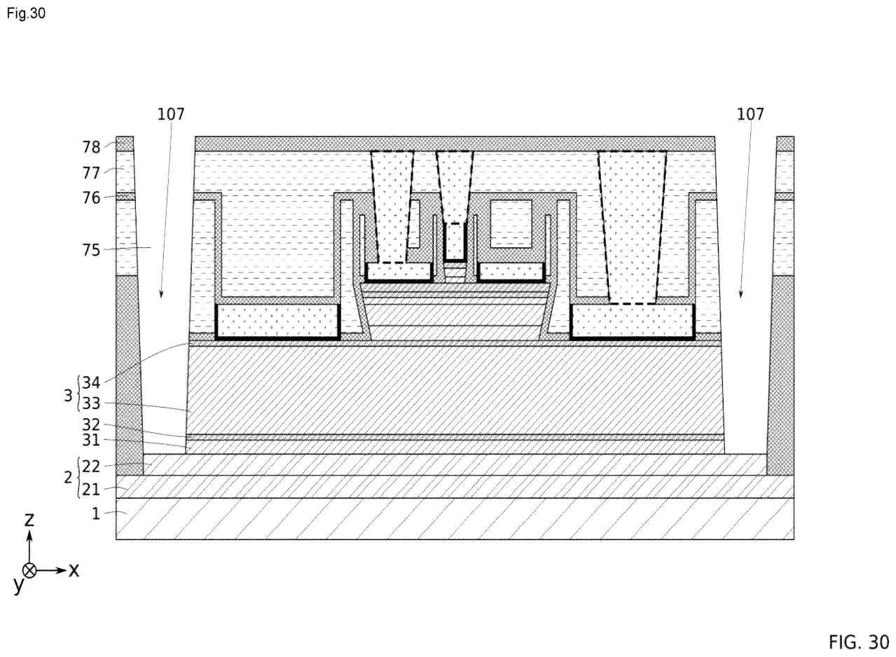

As illustrated in FIG. 30, after stripping of the masking layer 88, the etching of the trenches 107 is extended into the stack of layers with the basis of III-V materials, up to the SiO₂-based layer 2.

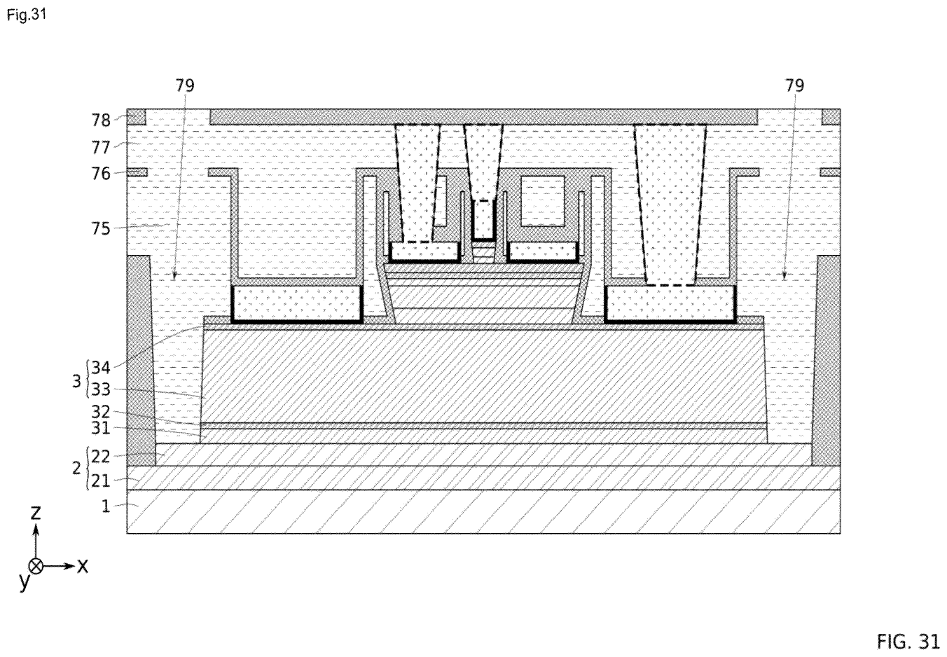

As illustrated in FIG. 31, these trenches 107 are then filled by a dielectric material 79, typically by TEOS SiO₂ deposition at 300° C. over a thickness of 2 μm. A chemical-mechanical polishing of the SiO₂ is then performed, stopping on the SiN-based layer 78.

The following steps aim to form the first metal level M1 comprising the metal tracks connecting the different interconnections 55, 65, 35. The interconnections 55, 65, 35 form an interconnecting level I1.

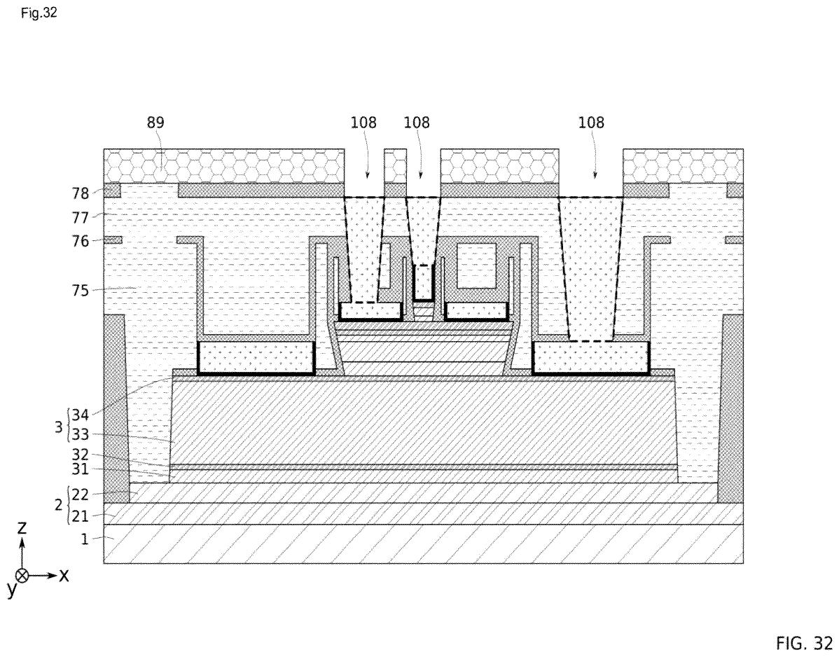

As illustrated in FIG. 32, a resin-based masking layer 89 is formed on the layer 78 and structured, typically by e-beam electron lithography. Openings 108 are made above the interconnections 55, 65, 35, first in the layer 89, then in the layer 78 up to the interconnections 55, 65, 35.

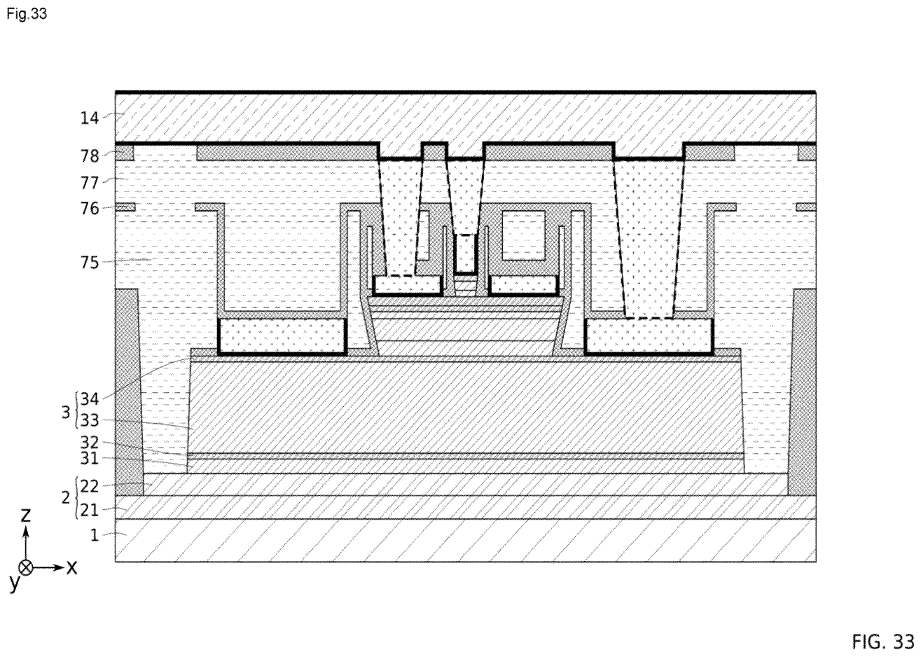

As illustrated in FIG. 33, after “stripping” of the masking layer 89, a deposition of a metal layer 14 is performed, so as to connect the interconnections 55, 65, 35. This metal layer 14 can comprise several sublayers, for example, Ti- and TiN-based sticking layers, of 10 nm thicknesses respectively, an AlCu alloy-based main layer, of 440 nm thickness, for example, and Ti- and TiN-based superficial layers, of 10 nm thicknesses respectively.

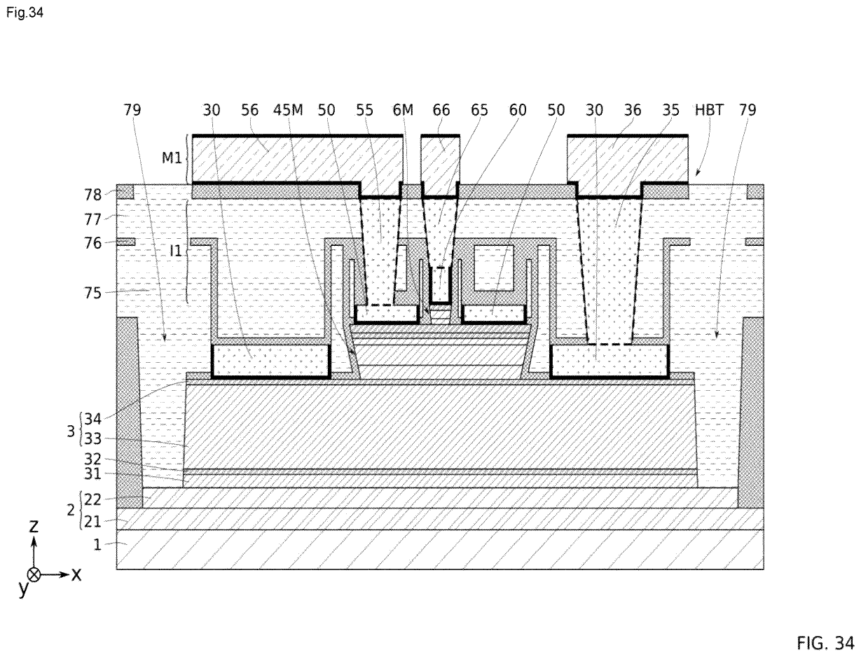

As illustrated in FIG. 34, this metal layer 14 is then structured by lithography and etching, so as to form a track 56 connected to the via 55, a track 66 connected to the via 65, and a track 36 connected to the via 35.

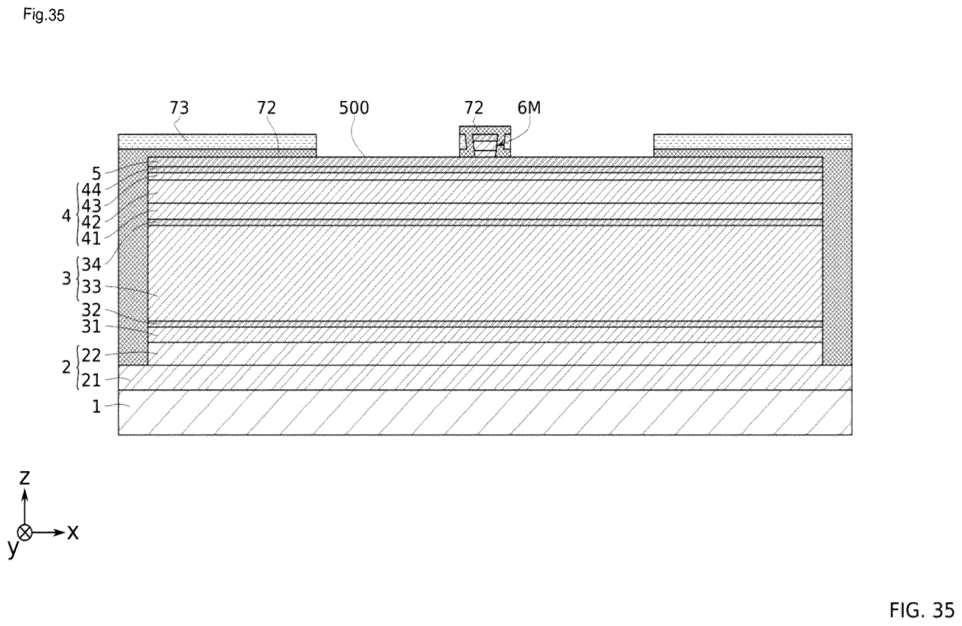

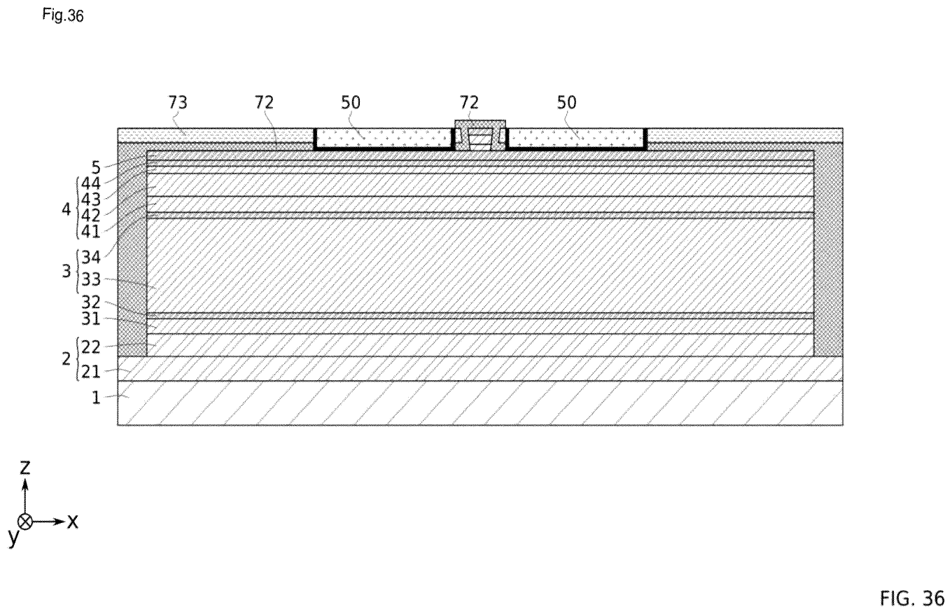

An HBT transistor comprising mesa structures 6M, 45M formed in a stack of III-V materials on Si substrate, integrated in SiO₂, SiN dielectric materials, and connected by W-based interconnections 55, 65, 35 is thus obtained. Such an HBT transistor and its first interconnecting level 11, M1 can be advantageously integrated in a system comprising CMOS transistors and CMOS interconnections. FIGS. 35, 36 illustrate a variant of the method for producing the HBT transistor, in which the base contacts are formed before the emitter contact.

As illustrated in FIG. 35, the mesa structure 6M is formed by lithography and etching from the stack of layers with the basis of III-V materials. Dielectric layers 72, 73 are then formed on this mesa structure 6M, then planarised. The dielectric layers 72, 73 are then opened at the border of the mesa structure 6M, so as to expose the upper face 500 of the layer 5.

As illustrated in FIG. 36, the openings are then filled by a metal layer. A CMP thus makes it possible to remove the excess metal layer parts to form the base contacts 50. The emitter contact and the collector contacts can then be formed as above. In this case, the upper face of the base contacts 50 is located in a plane corresponding substantially to the apex of the mesa structure 6M. It is therefore not necessary to taper the base contacts 50 when these are formed before the emitter contact. This makes it possible to save a method step.

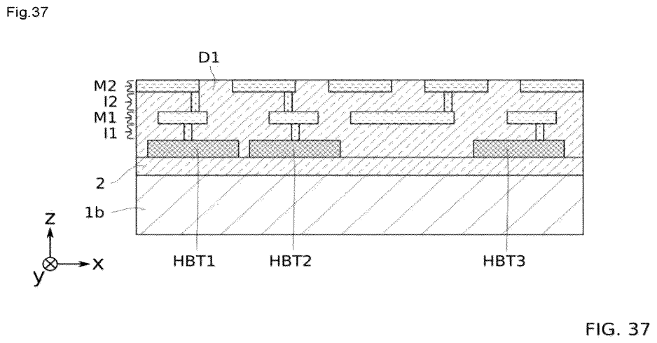

FIGS. 37, 38, 39, 40 illustrate options for integrating the HBT transistor in a system comprising CMOS transistors and CMOS interconnections.

As illustrated in FIG. 37, an integrated circuit comprising transistors HBT1, HBT2, HBT3 with the basis of III-V materials on a silicon-based substrate 1b, and integrated via interconnecting levels 11, 12 and metal levels M1, M2 in an SiO₂- and/or SiN-based dielectric matrix D1, can advantageously be obtained. The last metal level M2 of this “HBT” integrated circuit can typically form a first hybrid bonding interface.

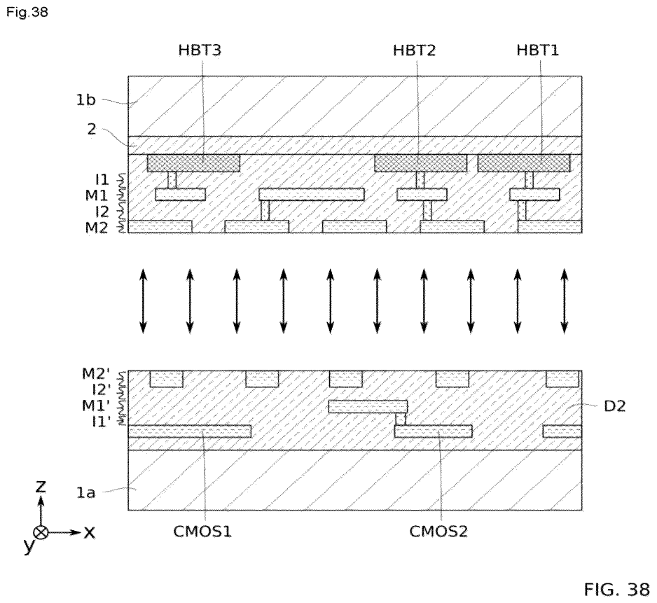

As illustrated in FIG. 38, a “CMOS” integrated circuit comprising CMOS- or BiCMOS-, CMOS1-, CMOS2- . . . transistor-based components on a silicon-based substrate 1b and integrated via interconnecting levels I1′, I2′ and metal levels M1′, M2′ in an SiO₂- and/or SiN-based dielectric matrix D2, can be advantageously assembled to the “HBT” integrated circuit. The last metal level M2′ of the “CMOS” integrated circuit can typically form a second hybrid bonding interface.

The “HBT” and “CMOS” integrated circuits can be aligned and assembled by hybrid bonding by facing the first and second hybrid bonding interfaces against one another. In the case of “HBT” integrated circuits of small lateral dimensions with respect to the “CMOS” integrated circuit, several “HBT” integrated circuits can be co-assembled side-to-side on the “CMOS” integrated circuit. After assembly, the substrate 1b can typically be removed by mechanical trimming and wet etching.

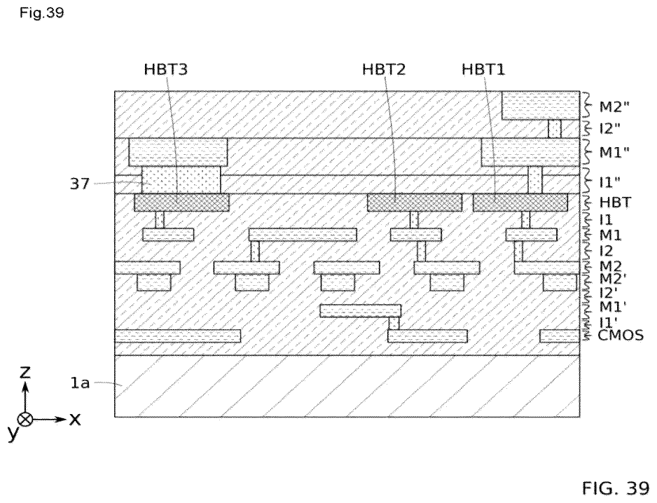

As illustrated in FIG. 39, interconnecting levels I1″, I2″ and metal levels M1″, M2″ in an SiO₂- and/or SiN-based dielectric matrix D3, can be advantageously formed above the transistors HBT1, HBT2, HBT3 with the basis of III-V materials. The interconnecting level I1″ advantageously connects the transistors HBT1, HBT2, HBT3, typically at the collector or subcollector part of the transistors HBT1, HBT2, HBT3. Certain interconnections 37 of the level I1″ can be relatively wider and bulkier to form a radiator for the corresponding transistor HBT3. This improves the thermal dissipation and the management of the heating of such a transistor HBT3. The metal levels M1″, M2″ can typically comprise thick metal tracks, forming passive RF components, such as antennas or transmission lines.

Advantageously, the HBT level can be integrated between different interconnecting levels, for example, between the interconnecting levels I1, I1″ such as illustrated, or between the interconnecting levels I1″, I2″, etc. This enables a greater versatility in integration of the HBT transistors within the CMOS stack. Several CMOS metal levels M1′, M2′, for example, up to five levels, can be provided under the HBT level. Several post-treatment metal levels M1″, M2″, for example, up to five additional levels, can be provided above the HBT level.

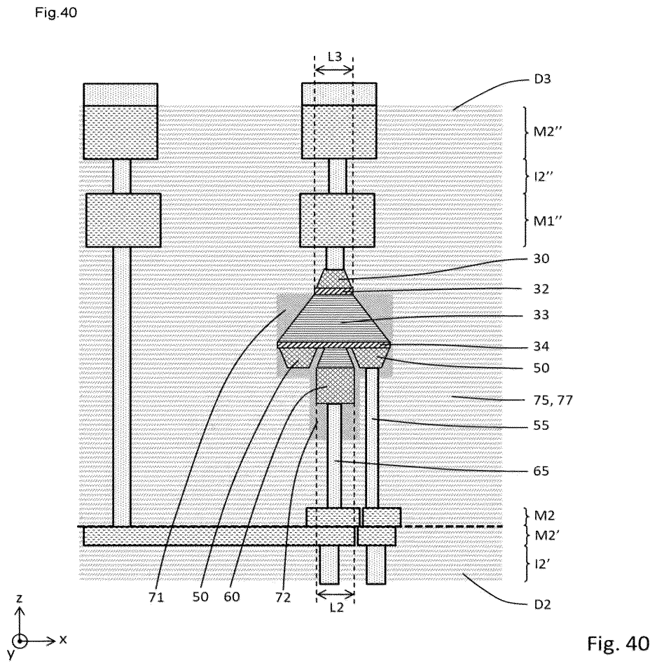

As illustrated in FIG. 40, the collector contact 30 can be formed in the “rear face” of the HBT transistor during subsequent integration steps, after removal of the silicon-based substrate 1. The layer 32 is typically, in this case, doped InGaAs-based. The emitter 60 and base 50 contacts, as well as the reconnections 55 and 65 are formed beforehand, for example, up to the metal level M2 and enable the transfer by “Direct Hybrid Bonding” of a wafer comprising different metal levels M2′ or greater. The metal levels M1″, M2″ correspond, in this case, for example, at thick metal levels implemented in CMOS or BiCMOS technologies. The formation of the collector contact 30 in the “rear face” enables a better thermal dissipation for the HBT transistor, and less thermal resistance between the bases 50 and the collector 30. The overall resistance of the collector 30 is decreased. The formation of the collector contact 30 in the “rear face” also offers more options in terms of design of the collector contact 30. According to an option illustrated in FIG. 40, the collector contact 30 has a dimension L3 substantially equal to the dimension L2 of the emitter contact. The metal surfaces opposite one another between collector 30 and bases 50 are decreased. This reduces the parasitic capacities between the base contacts 50 and the collector contact 30. The thermal management and the management of the parasitic capacities are improved. The InP-based layer 33 typically has a dielectric constant of around 13. It is surrounded by layers 71, 72 with the basis of a dielectric material having a dielectric constant less than that of the InP and the InGaAs. For example, this material can be silicon nitride having a dielectric constant of around 7. The surrounding matrix, comprising the silicon oxide-based layers 75, 77, typically has a dielectric constant of around 4.

The interconnecting I2′ and metal M2′ levels formed beforehand on another wafer which constitutes the accommodating wafer or “Bottom”, and can be a BiCMOS circuit, for example. This makes it possible to consider other improvements and functionalisations of the device during back end of line steps. This integration in the front face and/or in the rear face of the HBT transistor by “Direct Hybrid Bonding”, which requires an excellent surface planarity between the different wafers and chips, is in particular made possible by the planarisation steps occurring during manufacturing bricks of the HBT transistors.

In view of the above, it clearly appears that the HBT transistor and its integration system can be integrated compactly and in a versatile manner within a CMOS or BiCMOS integrated circuit. The invention is not limited to the embodiments described above.

1. A method for producing a heterojunction bipolar transistor, the method comprising:
providing a stack comprising, along a direction z, a silicon-based substrate, a first layer made of a first III-V material, having a first type of conductivity with a first N+ doping level,
forming, by epitaxy, on the first layer of a collector layer, with a basis of a second III-V material having the first type of conductivity with a second N doping level,
forming, by epitaxy, on the collector layer of a base layer, with a basis of a third III-V material having a second type of conductivity with a first P+ doping level,
forming, by epitaxy, on the base layer of a emitter layer, with a basis of a fourth III-V material having the first type of conductivity with a third N doping level,
a first mesa-form structuration of the collector and base layers, configured to form a first mesa structure having a dimension L1 along a direction y perpendicular to the direction z,
a second mesa-form structuration of the emitter layer, configured to form a second mesa structure having a dimension L2 less than the dimension L1 along the direction y,
forming a collector contact on the first layer, at the border of the first mesa structure,
forming a base contact on the base layer, at the border of the second mesa structure,
forming an emitter contact on the emitter layer, said collector, base, and emitter contacts being formed with a basis of an electrically conductive material, suitable for a metallurgy of the metal levels of a complementary metal-oxide-semiconductor (CMOS) transistor-based integrated circuit,
forming at least one encapsulation layer covering the first layer, the first and second mesa structure, and the collector, base and emitter contacts said encapsulation layer being formed with a basis of a dielectric material, suitable for an insulation of the metal levels of the CMOS transistor-based integrated circuit, and
planarizing the at least one encapsulation layer.

2. The method according to claim 1, wherein the forming of the first and second mesa structures is performed respectively by a first etching along z of the collector and base layers and by a second etching along z of the emitter layer.

3. The method according to claim 2, wherein the first and second etchings each comprise a wet isotropic etching step, such that the first and second mesa structures each have inclined flanks, respectively overhanging the first layer and the base layer.

4. The method according to claim 1, wherein the following steps are performed in the following chronological order: the forming of the emitter contact, the forming of the second mesa structure, the forming of the base contact, the forming of the first mesa structure, and the forming of the collector contact.

5. The method according to claim 1, wherein the following steps are performed in the following chronological order: the forming of the second mesa structure, the forming of the base contact, the forming of the emitter contact, the forming of the first mesa structure, and the forming of the collector contact.

6. The method according to claim 1, wherein the forming of the collector contact and/or the forming of the base contact comprise a first tungsten nitrogen plasma-enhanced deposition to form a peripheral portion of the collector contact and/or of the base contact respectively, said forming further comprising tapering the peripheral portion of the contact considered by etching of the peripheral portion of the contact considered with respect to a central portion of said contact.

7. A heterojunction bipolar transistor comprising, in a stack along a direction z on a silicon-based substrate:
a first layer made of a first III-V material having a first type of conductivity with a first N+ doping level,
a first mesa structure on the first layer, comprising collector layer, with a basis of a second III-V material having the first type of conductivity with a second N doping level, and a base layer, with a basis of a third III-V material having a second type of conductivity with a first P+ doping level, and
a second mesa structure on the first mesa structure, comprising an emitter layer with a basis of a fourth III-V material having the first type of conductivity with a third N doping level,
said transistor (HBT) further comprising a collector contact on the first layer, at a border of the first mesa structure, a base contact on the base layer, at the border of the second mesa structure, an emitter contact on the emitter layer, said collector, base, and emitter contacts being with a basis of an electrically conductive material, suitable for a metallurgy of the metal levels of a complementary metal-oxide-semiconductor (CMOS) transistor-based integrated circuit, p1 said transistor (HBT) further comprising an encapsulation layer a basis of a dielectric encapsulation material, said encapsulation layer covering the first layer, the first and second mesa structures and the collector, base, and emitter contacts, said encapsulation layer being with a basis of a dielectric material, suitable for an insulation of the metal levels of the CMOS transistor-based integrated circuit, and
wherein the base contact has a central portion and a peripheral portion around the central portion, such that the peripheral portion has a thickness less than that of the central portion and which decreases by moving away from the central portion, so as to decrease a parasitic capacity between the base contact and the emitter contact.

8. The transistor according to claim 7, wherein the dielectric material is taken from among SiO₂, SiN, SiOC, HfO₂, and Al₂O₃, and the conductor material is taken from among W, Ti, TiN, Cu Ni, NiSi, NiPt, Mo, and Al.

9. The transistor according to claim 7, wherein the first and fourth III-V materials are InP-based, and the second and third III-V materials are InGaAs-based.

10. The transistor according to claim 7, wherein the collector contact has a central portion and a peripheral portion around the central portion, such that the peripheral portion has a thickness less than that of the central portion and which decreases by moving away from the central portion, so as to decrease a parasitic capacity between the collector contact and the base contact and/or the emitter contact.

11. A system for integrating at least one heterojunction bipolar transistor (HBT), comprising, in a stack along a direction z:
a first silicon-based substrate,
a layer comprising complementary metal-oxide-semiconductor (CMOS) transistors and first metal interconnecting levels connected to said CMOS transistors,
a bonding layer comprising a hybrid bonding-type interface, comprising electrical connections with the first metal interconnecting levels connected to the CMOS transistors, and
a layer (HBT) comprising at least one heterojunction bipolar transistor according to claim 7, and second metal interconnecting levels inserted between the bonding layer and the layer (HBT) comprising the at least one heterojunction bipolar transistor, said second metal interconnecting levels being electrically connected to the bonding layer and to the at least one heterojunction bipolar transistor.

12. The integration system according to claim 11, further comprising, on the layer comprising the at least one heterojunction bipolar transistor, at least one third interconnecting level comprising a thick metal layer having a thickness at least twice greater than the different metal thicknesses of the first and second metal interconnecting levels located under the layer comprising the at least one heterojunction bipolar transistor.

13. The integration system according to claim 12, wherein the thick metal layer is connected to the first layer made of a first III-V material of the heterojunction bipolar transistor by an electrical connection of thermal dissipation, said electrical connection of thermal dissipation acting as a collector contact for the heterojunction bipolar transistor.

14. The integration system according to claim 11, wherein the first layer made of a first III-V material of the layer comprising the at least one heterojunction bipolar transistor is continuous and covers, projecting along the direction z, totally the first silicon-based substrate.

15. The integration system according to claim 11, wherein the first metal interconnecting levels connected to the CMOS transistors comprise between three and five metal layers.

16. A method for integrating at least one heterojunction bipolar transistor, the method comprising:
providing a first stack, comprising along a direction z:
a first silicon-based substrate,
a layer comprising complementary metal-oxide-semiconductor (CMOS) transistors and first metal interconnecting levels connected to said CMOS transistors, and
a first part of a bonding layer comprising a hybrid bonding-type interface, comprising electrical connections with the first metal interconnecting levels connected to the CMOS transistors,
providing a second stack, comprising along a direction z:
a second silicon-based substrate,
a layer (HBT) comprising at least one heterojunction bipolar transistor (HBT) according to claim 7, and second metal interconnecting levels connected to said heterojunction bipolar transistor, and
a second part of a bonding layer comprising a hybrid bonding-type interface, comprising electrical connections with said second metal interconnecting levels connected to the heterojunction bipolar transistor,
hybrid bonding of the second part of the bonding layer on the first part of the bonding layer,
removing the second silicon-based substrate, and
forming, on the layer comprising the at least one heterojunction bipolar transistor, of at least one third interconnecting level, said at least one third interconnecting level comprising a so called thick metal layer having a thickness at least twice greater than the different metal thicknesses of the first and second metal interconnecting levels located under the layer (HBT) comprising the at least one heterojunction bipolar transistor.
